(19) United States
(12) Patent Application Publication
(10) Pub. No.: US 2026/0323824 A1
(43) Pub. Date: Oct. 15, 2026

(54) PRINTED CIRCUIT BOARD CONTAINING POWER CONDUCTOR AND METHOD OF MAKING THE SAME

(71) Applicant: Kuprion, Inc., Waterbury, CT (US)

(72) Inventors: Alfred A. Zinn, San Jose, CA (US); Cynthia Garcia, Santa Cruz, CA (US); Hannah Thanh Zinn, Palo Alto, CA (US); Alex Capanzana, San Jose, CA (US); Agustin Vega, Hayward, CA (US); Nicholas Antonopoulos, San Jose, CA (US)

(21) Appl. No.: 19/633,277

(22) Filed: Mar. 30, 2026

Related U.S. Application Data
(63) Continuation-in-part of application No. 19/174,561, filed on Apr. 9, 2025.

(51) Int. Cl. H05K 1/09

(52) U.S. Cl. CPC H05K 1/09

(57) ABSTRACT

A printed circuit board assembly comprising (a) a printed circuit board, wherein the at least one printed circuit board comprises at least one insulating layer, and (b) one or more structures formed in the printed circuit board, wherein the one or more structures extends across a dimension of the printed circuit board and are at least substantially filled with a conductive material to form one or more conductive structures. The one or more conductive structures are configured to transmit direct current across the dimension of the printed circuit board.

### FIELD OF THE INVENTION

The present invention relates generally to a printed circuit board assembly comprising one or more conductive structures therein capable of jetting power across the printed circuit board and a method of making the same.

### BACKGROUND OF THE INVENTION

In high power applications, multiple components for all or a portion of a circuit can be packaged in electronic “power” modules, which may be housed in a thermoplastic, epoxy, or like molded housing to encapsulate the components and the circuit board or substrate on which the components are mounted. The input/output connections for these power modules are provided by terminal assemblies that extend out of the housing to facilitate incorporation in and connection to other systems. Such systems may include electric vehicles, power conversion and control, artificial intelligence (“AI”), high power communication systems (including satellite and ground stations) and the like. In other words, a power semiconductor module is a device/system/configuration comprising one or more semiconductor chips and components for electrically connecting and mechanically supporting one or more power semiconductor chips.

Power modules provide a physical containment for power components such as power semiconductor devices that are situated (e.g., by soldering or sintering) on a power electronic substrate. The power module may include an advanced integrated circuit (IC) substrate and/or other substrate(s) that are configured to serve as a foundation for mounting and interconnecting ICs within electronic devices. The power modules also typically utilizes advanced materials and technologies to provide optimal electrical performance, thermal management, and signal integrity.

Electric vehicles (EV) may include a hybrid set of technologies throughout their various systems, including an energy storage system to store and distribute large amounts of electrical energy and that is controlled using high-performance semiconductor devices for very fast switching (i.e., to drive an electric motor, among other purposes). There are many challenges to combining these diverse technologies in a single operational circuit to allow very large currents to be distributed and controlled.

“Artificial intelligence” may be defined as software that mimics and generates human-like behaviors and one function of AI is the minimization of energy consumption, both at home and in industry. However, AI computing consumes huge amounts of power, both in its “learning” phase and during routine use. Large data centers may require a feed of more than 100 MW and it would be desirable to improve/optimize the distribution of current within such systems. In addition, there are many considerations when designing a power distribution system in a data center, including voltage and current levels for safety and loss consideration in distribution and conversion, the need for functional and/or safety isolation, the physical size of power conversion stages, cooling arrangements, etc. Also, as power levels have increased, power density of conversion has become more of an issue which has an increased emphasis on efficiency.

Large trenches (as compared with small thinner conduction lines) stay cooler and are more efficient during power delivery. Large trenches also take up much less space. In contrast, thinner lines exhibit higher resistance and heat up faster when more power is run through them, causing thermal management challenges, consuming more power, which in turn requires more cooling and may also lead to thermal runaway.

Copper and copper alloys are well-known materials for electrical and electronic components and for power distribution members through which large currents flow. However, it is critical that the copper or copper alloy material be able to maintain high reliability without any decrease in strength even when used in harsh environments.

U.S. Pat. Pub. No. 2008/0106875 to Igarashi et al., the subject matter of which is herein incorporated by reference in its entirety, describes a hybrid integrated circuit device that includes conductive patterns formed on a front surface of a circuit substrate and circuit elements electrically connected to the conductive patterns. However, it is difficult to ensure a sufficient current-carrying capacitance due to the small cross-sectional area of the thin conductive pattern.

Various methods have been used convey power across a printed circuit board. One process is a subtractive process in which thin sheets of copper are bonded to glass fiber or epoxy layers. These layers are then hot pressed to bind the stack of layers together, creating layers of copper within the printed circuit board. Another process involves creating a pattern which may be filled with electroplated copper. However, this a relatively slow process and can take up to 12 hours or more, depending on the depth of the pattern to be filled, and is generally only effective for low aspect ratio holes that are relatively small; larger structures could take days or even weeks to fill. In addition, there are often structural issues and other growth characteristics that can adversely impact performance.

While various strategies have been developed to incorporate conductive layers and/or conduits for thermal or electrical conductivity in a printed circuit board, there is a growing desire for improvements to allow for higher carrying power across a semiconductor device or module, especially for use in high power applications such as server farms, electrical vehicles, and artificial intelligence data farms. This has not been a focus in printed circuit board development, leaving many users to try to figure out how to use existing products that may be incapable of meeting their needs.

Thus it would be desirable to provide an improved highly conductive material that is capable of conveying high power through a printed circuit board or other assembly. In addition, it would also be desirable to provide a configuration that does not get overly hot during use. In other words, the goal is the ability to conduct more power across the printed circuit board or other assembly in an efficient manner and to provide increased performance.

It is also known that in larger devices, conductive layers and/or conduits may exhibit more cracking and shrinkage. Thus, it is desirable to produce a conductive layer or structure in a printed circuit board or other assembly that does not exhibit cracking or shrinkage and that therefore exhibits greater reliability.

### SUMMARY OF THE INVENTION

It is an object of the present invention to provide a printed circuit board or other assembly for high power applications, including, for example, server farms, electric vehicles, and artificial intelligence data centers.

It is another object of the present invention to provide a conductive structure in a printed circuit board suitable for conducting high power and that does not exhibit any cracking or shrinkage.

It is still another object of the present invention to provide a conductive structure in a printed circuit board or other assembly that exhibits high reliability.

It is still another object of the present invention to provide a conductive structure that is fully buried or embedded inside a printed circuit board (similar to a blind via structure) that exhibits high conductivity and reliability and is configured for carrying high power through a printed circuit board.

It is still another object of the present invention to provide a conductive structure that is embedded inside a printed circuit board and that extends across an entire thickness of the printed circuit board and that exhibits high conductivity and reliability and is configured for carrying high power through a printed circuit board.

It is still another object of the present invention to provide one or more structures (including, e.g., one or more trenches, grooves, and/or vias) that are filled with a conductive material to form one or more conductive structures and in which the conductive material is capable of and/or configured for carrying high power through a printed circuit board or device and/or across multiple printed circuit boards or devices and across greater distances.

It is another object of the present invention to provide one or more conductive structures in a printed circuit board and in which the conductive structures are at least substantially resistant to shrinkage.

It is another object of the present invention to provide one or more conductive structures that are CTE matched to the PCB, ceramic or other circuit board material for highest reliability.

It is another object of the present invention to provide one or more conductive structures in a printed circuit board that are at least substantially resistant to cracking.

It is still another object of the present invention to provide one or more conductive structures in a printed circuit board and in which the conductive structures exhibit high reliability.

To that end, in one embodiment, the present invention relates generally to a printed circuit board assembly comprising:
a. a printed circuit board, wherein the at least one printed circuit board comprises at least one insulating layer;
b. one or more conductive structures in the printed circuit board, formed in the printed circuit board, wherein the one or more conductive structures extend substantially across a dimension of the printed circuit board;
   and
   wherein the one or more conductive structures are configured to transmit direct current across the dimension of the printed circuit board.

In one embodiment, the present invention also relates generally to a method comprising:
a. forming one or more structures in a printed circuit board, each of the one more structures extending substantially across a dimension of the printed circuit board, and wherein the printed circuit board comprises at least one insulating layer;
b. filling each of the one or more structures with a conductive material to form one or more conductive structures, wherein the conductive material comprises a metal nanoparticle paste composition; and
c. consolidating the conductive material using heat and/or pressure to form a monolithic metal body within each of the one or more structures, wherein the monolithic metal body at least substantially fills the one or more structures;
   wherein the one or more conductive structures are capable of transmitting direct current across the dimension of the printed circuit board when connected to a power source.

### BRIEF DESCRIPTION OF THE DRAWINGS

Features and aspects of embodiments are described below with reference to the accompanying figures, in which elements are not necessarily depicted to scale, and in certain views, parts may have been exaggerated or removed for purposes of clarity.

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and the benefit of the disclosure.

Exemplary embodiments of the present disclosure are further described with reference to the appended figures. It is to be noted that the various features, steps and combinations of features/steps described below and illustrated in the figures can be arranged and organized differently to result in embodiments which are still within the scope of the present disclosure.

FIGS. 1 and 2 depict presumed structures of metal nanoparticles having a surfactant coating thereon.

FIGS. 3A and 3B depict a top and side view of a printed circuit board containing conductive trenches or grooves in accordance with one embodiment of the present invention.

FIGS. 4A and 4B depict a top and side view of a printed circuit board containing a conductive through-hole power via or coin in accordance with one embodiment of the present invention.

FIG. 5 depicts a cross-sectional view of a fully embedded conductive conduit arranged between two components.

Like parts are marked throughout the specification and drawings with the same reference numerals, respectively.

### DETAILED DESCRIPTION OF THE PREFERRED EMBODIMENTS

As described herein, the present invention relates generally to a printed circuit board or device that comprises one or more structures filled with a conductive material to form one or more conductive structures that are capable of and configured for conducting (i.e., transmitting) power (in the form of direct current) through and/or across a dimension of the printed circuit board or other electronic device. The present disclosure also relates generally to circuit board technology and, more specifically, to techniques for transmitting and distributing power in, through, and around printed circuit boards (PCBs) and related electronic systems, which may be accomplished by the conductive metal-filled structures described herein.

After processing, the conductive material within the each of the structures constitutes a solid conductive bulk metal in a prescribed state that is capable of and/or configured for conducting and transmitting high power through/across the printed circuit board or other electronic substrates.

The conductive structures described herein are designed or configured for conducting high power through the printed circuit board or device. In other words, the conductive structures are not designed or configured for conducting a signal through the printed circuit board or device, which signal is generally conducted on a low voltage, low current path. Instead, the conductive structures can conduct power at high voltage and high current, i.e., at full speed, because they are configured to jet power.

The conductive structures may include, for example one or more trenches, grooves, conduits, vias, including through-hole power vias, coins, fully embedded wires/cables, other similar structures, and combinations of any of the foregoing. For example, conductive trenches or grooves may extend across a width/length of the circuit board/substrate and are operatively connected to a power source so that power (i.e., in the form of direct current) can be conducted and/or transmitted at full speed across the printed circuit board. Conductive through-hole power vias and coins may extend across a thickness of the circuit board/substrate to feed power from both sides of the printed circuit board. Conductive wires or conduits may be partially or fully embedded in the printed circuit board.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

As used herein, “a,” “an,” and “the” refer to both singular and plural referents unless the context clearly dictates otherwise.

As used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform herein. Furthermore, it is also to be understood that the value to which the modifier “about” refers is itself specifically disclosed herein.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As used herein the term “substantially-free” or “essentially-free” if not otherwise defined herein for a particular element or compound means that a given element or compound is not detectable by ordinary analytical means that are well known to those skilled in the art of metal plating for bath analysis. Such methods typically include atomic absorption spectrometry, titration, UV-Vis analysis, secondary ion mass spectrometry, and other commonly available analytically methods.

It is noted that reference may be made individually to at least one “trench,” “groove,” “via,” “coin,” “conduit,” “wire,” and/or other structure or may be made to plural “trenches,” “grooves,” “vias,” “coins,” “conduits,” “wires,” and/or other structures.

As used herein, the term “through-hole power via” refers to a structure that extends from a first lateral surface to a second lateral surface of a substrate (i.e., printed circuit board) and that, when filled with a conductive material, is of a sufficient size and configuration to transmit direct current across a dimension of the substrate.

As used herein, the term “metal nanoparticle” refers to metal particles that are about 300 nm or less in size, preferably about 250 nm or less in size, preferably about 200 nm or less in size, more preferably about 100 nm or less in size without particular reference to the shape of the metal particles.

As used herein, the term “micron-scale metal particles” refers to metal particles that are about 500 nm or greater in size, or at least about 1000 nm or greater in size, or at least about 2500 nm or greater in size, or at least about 4000 nm or greater in size in at least one dimension. In some embodiments, the micro-scale metal particles may be in the range of about 1 to about 100 microns, or about 2 to about 75 microns or about 20 to about 60 microns.

The terms “consolidate,” “consolidation” and other variants thereof are used interchangeably herein with the terms “fuse,” “fusion” and other variants thereof.

As used herein, the terms “partially fused,” “partial fusion,” and other derivatives and grammatical equivalents thereof refer to the partial coalescence of metal nanoparticles with one another. Whereas totally fused metal nanoparticles retain only minimal structural morphology of the original unfused metal nanoparticles (i.e., they resemble a dense, bulk metal state with grain sizes in the 100-600 nm range), partially fused metal nanoparticles retain at least some of the structural morphology of the original unfused metal nanoparticles, such as a higher level of porosity, a smaller average grain size and crystal domain size, and a significant number of grain boundaries.

As used herein the term “high power” refers to direct current that may be transmitted or conducted through the conductive structure (e.g., trench or groove) formed in the printed circuit board, for example, which power may have a magnitude of greater than 18 Amps (based on an 850×600 micron cross-section trench).

Table 1 below sets forth a standard rating of traces in a printed circuit board and Table 2 below sets forth a rating of conductive trenches formed in the manner described herein related to size.

TABLE 1
Standard rating of traces in a printed circuit board
1 oz trace in PCB

| | Width | Area | |
|---|---|---|---|
| | (micron) | (micron²) | amps |
| Thickness | 250 | 9500 | 1 |
| 1 oz = 38 micron | 750 | 28500 | 2 |
| | 1250 | 47500 | 3 |
| | 2000 | 76000 | 4 |
| | 2750 | 104500 | 5 |
| | 3750 | 142500 | 6 |
| | 4500 | 171000 | 7 |
| | 5500 | 209000 | 8 |
| | 6500 | 247000 | 9 |
| | 7500 | 285000 | 10 |

TABLE 2
Rating of conductive trenches
Trench

| Width | Depth | Area | |
|---|---|---|---|
| (micron) | (micron) | (micron²) | Amps |
| 500 | 500 | 250000 | 9 |
| 850 | 600 | 510000 | 18 |
| 1000 | 1000 | 1000000 | 35 |
| 2000 | 2000 | 4000000 | 140 |

TABLE 3
Rating of conductive trenches - thermal performance

| | | | Thermal | Thermal |
|---|---|---|---|---|
| Width | Length | Thickness | conductivity | resistance |
| (mm) | (mm) | (mm) | (W/m*K) | (K/W) |
| 10 | 10 | 1.6 | 250 | 0.0640 |
| 10 | 10 | 3 | 250 | 0.1200 |
| 10 | 10 | 5 | 250 | 0.2000 |
| 10 | 10 | 1.6 | 300 | 0.0530 |
| 10 | 10 | 3 | 300 | 0.1000 |
| 10 | 10 | 5 | 300 | 0.1660 |
| 10 | 10 | 1.6 | 350 | 0.0457 |
| 10 | 10 | 3 | 350 | 0.0857 |
| 10 | 10 | 5 | 350 | 0.1430 |
| 25 | 20 | 1.6 | 300 | 0.0107 |
| 25 | 20 | 3 | 300 | 0.0200 |
| 25 | 20 | 5 | 300 | 0.0330 |
| 5 | 5 | 3 | 300 | 0.4000 |

As described herein, copper nanoparticles and other metal nanoparticles may be contained with a nanoparticle paste composition which is consolidated to form bulk metal at low processing temperatures, thereby facilitating direct printing or deposition of the metal nanoparticle paste composition within the structure that is configured for conducting high power across a dimension (i.e., length, width, thickness) of a printed circuit board. The process described herein provides significant advantages over copper-based etching and electroplating procedures that have been utilized in conventional PCB manufacturing techniques and produces a conductive structure that is configured for and capable of transmitting and distributing high power in and through the printed circuit board.

Previously, the copper layer thickness was limited to one size (typical numbers are ½ oz-18 micron thick or 1 oz-37 micron thick Cu sheets (as set forth in Table 1 above)) across the entire PCB or within the PCB. Due to the subtractive process, anything unwanted is etched away, a lot of waste is generated (toxic) and much copper lost, increasing as the thickness of the sheet increases. In contrast, with the invention described herein, multiple sizes are readily implemented greatly widening design capabilities and minimizing/eliminating losses due to the use of an additive process.

In addition, it is a known problem that larger devices face greater shrinkage, issues with cracking, and other reliability issues and it is desirable to provide a method of conducting high power through such a semiconductor device that overcomes these identified problems.

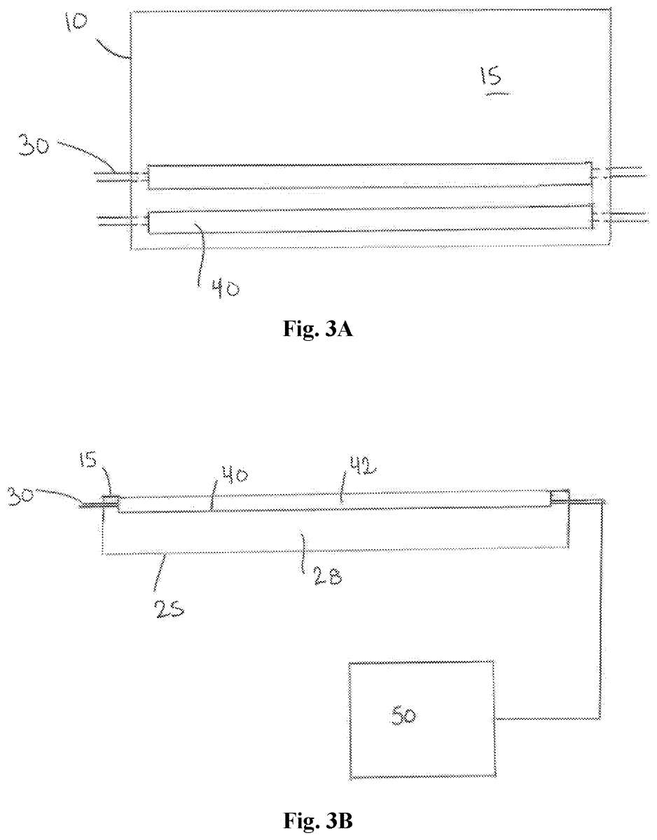

In one embodiment, and as shown in FIGS. 3A and 3B, the present disclosure relates generally to a printed circuit board assembly comprising:
a. a printed circuit board 10, wherein the at least one printed circuit board 10 comprises at least one insulating layer 28;
b. one or more structures 40 formed in a first face 15 of the printed circuit board 10, wherein the one or more structures 40 extend substantially across a dimension of the printed circuit board 10 and are at least substantially filled with a conductive material 42 to form one or more conductive structures;
   and
   wherein the one or more conductive structures are configured to transmit direct current across the dimension of the printed circuit board.

In one embodiment, the conductive material 42 comprises a monolithic block of bulk metal formed from a consolidation of a metal nanoparticle paste composition. In one embodiment, the monolithic block of bulk metal is a monolithic block of copper formed from the consolidation of a copper nanoparticle paste composition. The metal nanoparticle paste composition is preferably formulated to limit shrinkage during consolidation of the metal nanoparticle composition.

During consolidation, the metal nanoparticle paste composition forms the monolithic metal body that fills the structure 40, wherein the monolithic metal body preferably has a uniform nanoporosity ranging from about 2% to about 30%. As described herein, the one or more structures may include, for example one or more trenches, grooves, conduits, vias, fully embedded wires/cables, other similar structures, and combinations of any of the foregoing. These structures extend at least substantially across a dimension of the printed circuit board, which dimension may be length, width, or thickness depending on the nature of the one or more structures.

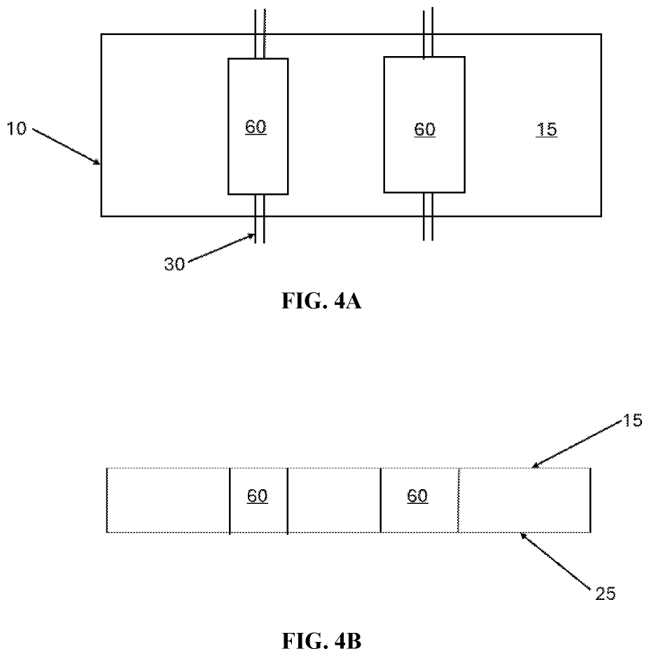

In some embodiments, the one or more structures may go all the way through the printed circuit board as shown, for example, in FIGS. 4A and 4B. As shown in FIGS. 4A and 4B, in some embodiments, the one or more structures comprise one or more through-hole power vias or coins 60 extending from a first face 15 to a second face 25 of a printed circuit board 10 and are at least substantially filled with a conductive material 42.

In some embodiments, the one or more structures may be embedded in the printed circuit board. In some embodiments, the one or more structures may be arranged on opposite side of the printed circuit board. In some embodiments, the one or more structures may comprise two or more different types of structures. For example, the two or more structures may comprise a combination of trenches and vias, a combination of blind vias and through-hole vias, a combination of trenches, blind vias, and through-hole vias, an embedded wire/cable and through-hole vias, etc.

In one embodiment, and as shown in FIGS. 3A and 3B, the one or more structures 40 comprise one or more trenches in a first face 15 of the printed circuit board 10 and having a depth that is less than the thickness of the printed circuit board 10. In one embodiment, the conductive trench or groove has a depth that is less than the thickness of the printed circuit board. Depending on the thickness of the printed circuit board 10, the conductive trench or groove may have a depth of between about 50 microns and about 3 mm, preferably about 150 microns and about 2 mm, more preferably about 500 microns and about 3 mm and a width of between about 100 microns and about 5 mm, more preferably about 500 microns and about 3 mm, or about 400 microns and 1000 microns, or about 750 microns and 2000 microns, or about 1 mm and 3 mm, or about 1.5 mm and 5 mm.

In one embodiment, the one or more trenches have a depth that extends at least substantially through the thickness of the printed circuit board.

In one embodiment, and as shown in FIGS. 4A and 4B, the one or more structures comprise one or more through-hole power vias or coins 60 that extend through the entire thickness of the printed circuit board 10. These structures may be of various shapes and sizes, depending on the thickness of the printed circuit board, size of the board, complexity of the printed circuit board and other factors. For example, in a thicker board, the cross-section of the one or more through-hole power vias 60 may be smaller as adequate power may pass through a greater thickness as compared with a thinner board, which would require a correspondingly larger through-hole power via or coin structure. In one embodiment, depending on the thickness and configuration of the printed circuit board, the through-hole power via or coin may have a largest dimension of up to 2 cm or up to 3 cm or more. That is, in one embodiment, the through-hole power via or coin may have a length of between about 500 microns and about 3 cm, or between about 1,000 microns and about 2.5 cm and a width of between about 50 microns and about 3 cm, or about 100 microns and about 3 cm or between about 500 microns and about 3 cm, or between about 1,000 microns and about 2.5 cm, or between about 5 mm and about 2.5 cm.

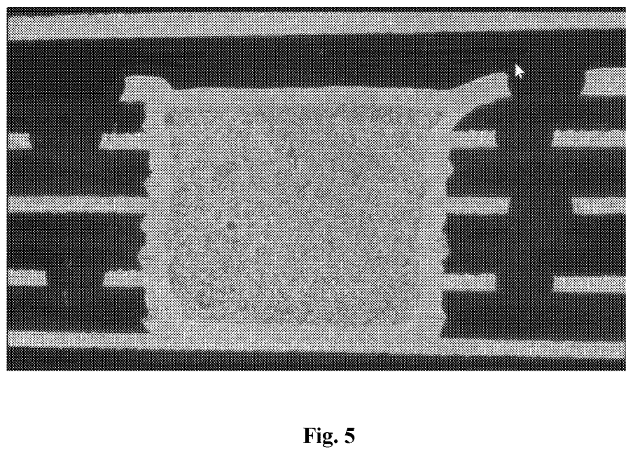

In one embodiment, and as shown in FIG. 5, the one or more structures comprises one or more embedded conduits or wires. Such one or more conduits or wires may be partially or fully embedded within the printed circuit board structures.

In one embodiment, the one or more structures comprise one or more blind and/or one or more through-hole vias, the one or more through-hole vias extending from a top surface of the printed circuit board to a bottom surface of the printed circuit board. In one embodiment, the one or more structures comprise one or more blind vias and one or more through-hole power vias or coins, the one or more through-hole power vias or coins extending from a top surface of the printed circuit board to a bottom surface of the printed circuit board.

In one embodiment, a conductive wire or other connection means 30 is disposed within at least a portion of the conductive material 42 and extends out of the printed circuit board 10. This conductive wire 30 is connectable to an external device 50. In one embodiment, the printed circuit board comprise a fastener (for example approximately 3-7 mm wide, 1-2 mm thick and extending out 5-10 mm on each side of the conductive wire or other connection means) to mechanically strengthen the connection at the end of the board and to prevent the conductive wire or other connection means 30 from being dislodged and various connection means may be used. In one embodiment, the fastener may be affixed, such as with an adhesive or mechanical fastener (i.e., screw) to the ends of the printed circuit board to provide mechanical strength proximate to the conductive wire or other connection means 30. While the conductive wire or other connection means 30 may be attached by soldering, the inventors have discovered that brazing provides good electrical connection and allows more power through with better reliability.

The external device 50 may be operatively connected to a source of power for transmitting current into and through the printed circuit board, which may comprise a power cord. Alternatively, the conductive wire or other connection means 30 may terminate into a connector that is secured to an edge of the printed circuit board.

In one embodiment, the at least one conductive structures, which may comprise one or more trenches or grooves, may comprise one or more bends or branches which may extend from the one or more conductive trenches or grooves to one or more edges of the printed circuit board 10. These one or more bends or branches form an angle with the one or more conductive trenches or grooves, wherein angle between the at least one or more bend and the at least one conductive trench or groove is between about 20 degrees to about 90 degrees, more preferably about 30 degrees to about 80 degrees, more preferably about 40 degrees to about 70 degrees or about 35 degrees to about 55 degrees.

In one embodiment, the one or more conductive structures have substantially the same cross-sectional shape across the entire length or width of the structure.

For example, when the one or more conductive structures comprise one or more conductive trenches or grooves, the cross-sectional shape may be in the form of a square, a V-shape, or a U-shape, by way of example and not limitation. In another embodiment, when the one or more conductive structures comprise one or more through-hole power vias or coins 45, the cross-sectional shape may be in the form of a circle, oval, multi-sided polygon, square, rectangle, or other similar shape, by way of example and not limitation.

In another embodiment, the side walls of the one or more trenches or grooves are angled so that the one or more trenches or grooves exhibits a substantially trapezoidal cross-sectional shape. This trapezoidal cross-sectional shape may be wider at the top of the one or more trenches or grooves and smaller at the bottom of the one or more trenches or grooves. The benefits of angling the side walls of the trench include better compaction of the copper and better or easier filling to completeness that helps prevents the formation of large voids. In one embodiment, the angle of the sidewalls, as measured relative to the planar surface of the printed circuit board is between about 45 and about 90 degrees, more preferably about 50 to about 80 degrees or about 60 to about 75 degrees.

It is also contemplated that the at least one or more conductive structures such as one or more trenches or grooves may be formed in both a top surface 15 and a bottom surface 25 of the printed circuit board. Thus, in one embodiment the printed circuit board assembly includes one or more conductive trenches or grooves formed in a second face 25 of the at least one printed circuit board 10 in addition to the one or more conductive trenches or grooves formed in a first face 15 of the printed circuit board 10. The one or more conductive trenches or grooves formed in the second face 25 of the printed circuit board may also extend substantially across a lateral dimension of the printed circuit board, have a depth that is less than the thickness of the printed circuit board 10, and be at least substantially filled with a conductive material 42. If the one or more trenches or grooves are formed in both the top surface 15 and the bottom surface 25 of the printed circuit board 10, the one or more trenches or grooves may be arranged in an alternating fashion so as to permit a greater depth and/or to extend through the entire depth of the printed circuit board. Alternatively, if the one or more trenches or grooves line up with each other from opposite sides of the printed circuit board, the one or more trenches or grooves may be shallower to ensure that the one or more trenches or grooves remain sufficiently separate from each other.

In one embodiment, when the one or more conductive structures comprise one or more vias, then one or more vias may be through-hole power vias or coins, blind vias, or a combination of through-holes and blind vias. In one embodiment, at least some of the blind vias are tapered. In one embodiment, the through-hole power vias or coins may be cylindrical or tapered, and the tapering may be in the cross-sectional center of the via or may be at one end of the vias.

In one embodiment, the one or more conductive structures comprise one or more partially or fully embedded wires or conduits. In one embodiment the one or more embedded wires or conduits may have a cross-sectional shape as described above for the one or more trenches.

In one embodiment, the one or more conductive structures may comprise two or more conductive structures of a different type or of a different size or of a different cross-section. As further described herein, one of the benefits of the instant invention is that these different conductive structures may be filled simultaneously in one processing step.

In one embodiment, the printed circuit board 10 with the one or more through-hole power vias or coins 60 disposed therein and filled with the conductive material 42 to produce a conductive through-hole power via or coins may be or operatively connected joined to a power connector affixed to a top of the printed circuit board 10 or to a CPU using the conductive wires or other connection means 30. In addition, the printed circuit board 10 may also be joined or operatively connected to a heat dissipation device (not shown) such as a heat pipe, oscillating heat pipe, heat sink, thermal ground plane, or other suitable device to effectively dissipate heat from the printed circuit board 10.

In one embodiment, the present invention relates generally to a method comprising:
a) forming one or more structures in a printed circuit board, wherein the printed circuit board comprises at least one insulating layer;
b) filling the one or more structures with a conductive material to form one or more conductive structures, wherein the conductive material comprises a metal nanoparticle paste composition; and
c) consolidating the conductive material using heat and/or pressure to form a monolithic metal body within each of the one or more structures, wherein the monolithic metal body at least substantially fills the one or more structures;
d) wherein a conductive structure is formed therein that is capable of transmitting power (i.e., direct current) across a dimension of the printed circuit board when connected to a power source.

In one embodiment, the metal nanoparticle paste composition comprises copper nanoparticles and the monolithic metal body is a monolithic copper body that is highly conductive.

Electrical conductivity is a measure of how well electrical current can pass through a material under the influence of an applied electric potential (voltage) or electrical field. It is the inverse of electrical resistivity, which measures how much of the electrical energy passing through a substance is lost as heat. The conductivity of copper alloys is usually expressed as % IACS, which is an acronym for the International Annealed Copper Standard. 100% IACS is defined as the conductivity corresponding to a volume resistivity at 20° C. of 17.241 nΩ·m, which was based on the expected typical conductivity of commercial (i.e., “pure”) annealed copper at the time the standard was adopted by the International Electrotechnical Commission in 1914. The higher the % IACS, the more conductive the material is. In one embodiment, the monolithic copper body formed within each of the one or more structures has a conductivity of at least 50% International Annealed Copper Standard (% IACS), preferably at least 55% IACS, preferably at least 60% IACS, or at least 70% IACS, or at least 80% IACS, or at least 90% IACS, or between 60 and 85% IACS.

In one embodiment, the monolithic metal body formed within each of the one or more structures has a uniform nanoporosity ranging from about 2% to about 30%.

In one embodiment, as discussed above, it may be desirable to form one or more trenches, grooves, and/or vias in both a top surface and a bottom surface of the printed circuit board. Thus, if desired, steps a) to c) may be repeated on a second face of the printed circuit board to create one or more conductive trenches, grooves, and/or vias on the second face of the printed circuit board.

In one embodiment, the step of forming the one or more structures in the printed circuit board comprises machining each of the one or more structures in the printed circuit board. However, other methods that are suitable for forming structures in a printed circuit board can also be used in the practice of the instant invention.

Filling of the structures with metal nanoparticles may take place by any suitable technique. Suitable techniques may include those in which the one or more structures are filled individually with metal nanoparticles, or those in which the one or more structures are filled substantially at the same time. In illustrative embodiments, syringes, syringe arrays, or other arrangements of dispensation devices containing the metal nanoparticle paste compositions may be used for filling the one or more structures. In other illustrative embodiments, printing techniques such as screen printing, stencil printing, or inkjet printing may be used to fill the one or more structures with the metal nanoparticle paste composition. In more specific embodiments, at least a portion of the one or more structures may be filled by screen printing the metal nanoparticle paste composition. Doctor blading techniques may also be utilized to fill one or more structures with a metal nanoparticle paste composition all at the same time or near the same time.

The technique for filling the structures may vary depending upon the size (diameter) of the structures. In illustrative embodiments, smaller trenches, grooves, through-hole power vias, or coins, such as those having a cross-sectional diameter of about 2 mm or about 3 mm in size or below, can be filled individually using a syringe or similar dispensation device followed by a squeegee step to smooth out the paste and ensure complete filling. Automated dispensation into each of the one or more structures may take place in some embodiments, such as with a robotically operated syringe, optionally incorporating a syringe pump. Arrays of syringes or similar arrangements of dispensation devices may be used to fill multiple structures simultaneously or near simultaneously. Larger trenches, grooves, through-hole power vias or coins, such as those that have a cross-sectional diameter of about 2 mm to about 7 mm in size or 3 mm to about 7 mm in size, or even larger, can also be filled individually or simultaneously using a syringe or similar dispensation device, in some embodiments, or more typically, by stencil printing or screen printing techniques using a suitable print head. As such, the structures, including trenches, grooves, through-hole power vias, and/or coins may be filled one at a time in some embodiments, or multiple structures may be filled with the metal nanoparticle paste compositions at substantially the same time, according to other embodiments. In some embodiments, each of the one or more structures may be filled with the nanoparticle paste composition at substantially the same time by first filling the one or more structures with the nanoparticle paste composition using a syringe and then leveling the paste by using a large squeegee across substantially the entire surface of the printed circuit board.

In one embodiment, the dispensing conditions for filling the one or more structures may include the use of a 10 ml syringe with a conical tip and an ID of 180 micron, allowing the nanoparticle paste composition to be dispensed at a pressure within the range of about 75 to about 280 psi, depending on paste density and viscosity. Other dispensing pressures include, about 90 to about 120 psi, or about 90 to about 150 psi or about 110 to about 160 psi, or about 120 to about 190 psi. Different size syringes or storage cartridges and tip sizes will require different dispensing pressures. Generally, large tip sizes reduce dispensing pressure, and smaller non-conical tips increase dispensing pressure. The tip should be as large or larger than the aperture of the trench/stencil being used. Smaller ones can be used as well but are not as efficient in filling such structures. For example, a 1 mm wide trench with a 1.5 mm stencil aperture would require the use of e.g., a 2 mm ID tip.

The inventors of the present invention have found that it is beneficial to use a stencil in order to overfill and account for shrinkage of the paste during processing. Excess copper paste can be polished away after consolidation or fusion. In one embodiment the stencil is about 100 to about 500 micron larger on each side compared to the dimensions of the structure (i.e., trench).

In one embodiment, such as when filling one or more through-hole power vias or coins 60, the stencil may also include a groove for placement of a power connector, such as a connecting wire 30, so that the stencil remains level with the surface of the printed circuit board when a wire, cable, or other structure is placed in the groove of the stencil and the wire, cable or other structure extends into the through-hole power via or coin 60 prior to filling the through-hole power via or coin 60 with the conductive material.

For example, in one embodiment, the one or more trenches or grooves may be filled by directly dispensing the conductive material into the one or more trenches or grooves.

In another embodiment, the one or more trenches or grooves may be filled by screen printing. In this instance, a template or stencil is first applied over the pre-formed trench or groove and then the conductive material is plated or otherwise dispensed into the trench. The use of the template or stencil allow for overfilling of the trench or groove, which accounts for shrinkage upon consolidation and thus allows for a more complete fill, contributing to greater reliability. When using a template, a slight angle (tapered aperture) may be used so that the filled area is slightly larger to account for shrinkage. Thus, in one embodiment, the use of the template or stencil permits the formation of rounded corners, which avoids the formation of large voids in the conductive material. The template or stencil is formed in the same pattern as the trench or groove being filled and is designed to account for shrinkage.

In one embodiment, the walls of the one or more structures may be electroplated with copper prior to filling with the nanocopper paste. Plating thickness may be, for example in the range of about 10 to about 100 micron or about 25 to about 80 micron or about 20 to about 60 micron or about 30 to about 50 micron, by way of example and not limitation.

Once the stencil or template is removed, the surface of the printed circuit board or other electronic substrate is preferably machined and/or polished so that each of the one or more conductive structures is at least substantially flush with the surface of the printed circuit board or other substrate. Thereafter, if desired, each of the one or more conductive structures may be coated with a surface finish. For example, the surface finish may comprise a precious metal final finish, such as a gold or gold alloy or a silver alloy final finish. If used, this final finish may have a thickness of less than about 10 micron, or less than 5 micron, or less than 3 micron, or less than 1 micron or less than 0.5 microns or less than 250 nm or less than 150 nm or between 50 and 150 nm.

In one embodiment, a conductive wire 30 is inserted within at least a portion of the conductive material 42 so that the conductive wire 30 extends out of the printed circuit board 10 and is connectable to an external device 50. This step is also preferably performed before consolidation of the conductive material so that the conductive wire is secured in the monolithic metal body within the one or more structures. The conductive wire may be operatively connected to an external power supply. In addition, as discussed above, the printed circuit board may comprise a fastener (for example approximately 3-7 mm wide, 1-2 mm thick and extending out 5-10 mm on each side of the conductive wire or other connection means) to mechanically strengthen the connection at the end of the board and to prevent the conductive wire or other connection means 30 from being dislodged and various connection means may be used. In one embodiment, the fastener may be affixed, such as with an adhesive or mechanical fastener (i.e., screw) to the ends of the printed circuit board to provide mechanical strength proximate to the conductive wire or other connection means 30.

Thereafter, as described above, once the one or more structures have been filled with conductive material by one of the methods described herein, the conductive material is consolidated using heat and/or pressure to form a monolithic metal body within each of the one or more structures, thus forming filled conductive structures that are capable of transmitting direct current across the printed circuit board.

As described herein, in one embodiment, the one or more conductive structures comprises one or more conductive through-hole power vias or coins that extend from a top surface to a bottom surface of the printed circuit board. One of the benefits of a conductive structure that extends from the top surface to the bottom surface of the printed circuit board is that pressure can be applied evenly on both the top surface and the bottom surface of the printed circuit board, ensuring more even and effective consolidation than may be achieved in a conductive structure that does not extend through the entire thickness of the printed circuit board.

Once the one or more conductive structures are formed within the printed circuit board, they may be joined to the printed circuit board assembly, such as by means of the conductive wire, to operatively connect the conductive trench or groove to a source of power for transmitting current into and through the printed circuit board. Thus, the one or more conductive structures are electrically connected to a power source to complete the circuit so that power can be conducted across the printed circuit board.

Other options for connecting the one or more conductive structures to a power source to connect the circuit include, but are not limited to, standard electrical connectors (high power), direct soldering/bonding with solder, and copper nanoparticle paste compositions as further described herein.

The current state of the art typically uses 6-8 copper layers/plies within the printed circuit board interspersed with ceramic or other layers to conduct power. In contrast, the present invention provides a much simpler printed circuit board configuration and eliminates and/or replaces the copper layers/plies with the one or more structures described herein. In other words, the one or more structures described herein effectively function as a high speed conductive cable incorporated directly into the printed circuit board itself to conduct power across the at least one printed circuit board in an efficient manner and with greater reliability.

The present disclosure provides an approach for filling one or more structures with a conductive material to establish one or more conduits that can conduct power laterally across a cross-section of a PCB or similar circuit board assembly (or alternative, across a thickness of a PCB or similar circuit board assembly from a top surface to a bottom surface) when connected to a power supply. Advantageously, the approaches described herein may be performed rapidly and at much lower cost than is possible with wholly electrodeposition approaches, while still readily affording a high-quality, large thermally conductive metal body that extend laterally across a cross-section of a PCB substrate. Because the various approaches of the present disclosure allow relatively large structures (including, but not limited to, trenches, grooves, vias, through-hole power vias, coins, embedded wires and/or conduits and other similar structures) to be filled with conductive metal in an efficient manner, a higher degree of thermal conduction may be realized as compared with that which may be obtained using conventional electrodeposition techniques.

The present disclosure utilizes metal nanoparticle compositions to affect filling of one or more structures for a thermally conductive pathway that extends laterally across a dimension of an insulating substrate of a PCB or similar circuit board assembly. The thermally conductive pathway formed from the metal nanoparticles may comprise a monolithic block of metal or a metal composite (equivalently referred to herein as a “monolithic metal block” or “monolithic metal body”). As discussed above, electrodeposition approaches are often difficult to perform and are at considerable risk of incomplete filling and/or void formation, thereby leading to poor thermal conduction. Such issues are much less prevalent when utilizing metal nanoparticles, thereby allowing trenches having a much larger cross-sectional profile to be filled with metal to conduct high power across the PCB or other similar device and to promote thermal transfer.

It is also contemplated that there may be difficulties associated with effective filling, cracking, delamination, and failure, particularly for trenches above a particular size, which problems may be solved by the method described herein.

U.S. Pat. Nos. 10,616,994 and 11,503,700 and U.S. Pat. Pub. No. 2021/0227680, all to Zinn, the subject matter of each of which is herein incorporated by reference in their entirety, are directed to the filling of vias in printed circuit boards or similar structures with a monolithic metal body to promote heat transfer. As described in Zinn, ineffective thermal communication between a heat source and a thermal management system like a heat sink can hamper dissipation of excess heat from a system. Electronic components, such as high-power LEDs and high-power circuitry, for example, are continually decreasing in size and becoming ever more powerful, thereby generating loads of excess heat that are increasingly being concentrated in smaller and smaller spaces. Growing production of excess heat and concentration thereof can make effective heat removal important yet especially problematic.

U.S. Pat. Pub. No. 2023/0065796 to Zinn et al., the subject matter of which is herein incorporated by reference in its entirety, describes printed circuit boards formed using ceramic substrates with high thermal conductivity to facilitate heat dissipation. Metal nanoparticles are used to form conductive traces and fill through-plane vias. Multi-layer printed circuit boards are described comprising two or more ceramic substrates adhered together, wherein each ceramic substrate has one or more conductive traces defined thereon and the one or more conductive traces are formed through consolidation of metal nanoparticles.

Metal nanoparticles are uniquely qualified for the applications described herein due to the moderate processing conditions needed for consolidating the metal nanoparticles together into a monolithic block of the corresponding bulk metal. Metal nanoparticles can be consolidated (fused) together into the corresponding bulk metal under a range of mild processing conditions that are significantly below the melting point of the metal itself. Due to copper's high thermal conductivity and relatively low cost, copper nanoparticles can be a particularly desirable type of metal nanoparticle for use in the various embodiments of the present disclosure. A monolithic block of copper formed within and filling one or more structures may function much more effectively for conducting power through/across the PCB than can a plurality of thin electrodeposited copper layers. Thus, when used for promoting electrical conductivity between/across various board layers, a monolithic copper block within each of the one or more structures may function in a largely similar manner to a plurality of electrodeposited copper layers in the same location.

In addition, if desired or needed, metal nanoparticle compositions may be further tailored to improve the thermal conductivity still further when filling one or more structures. In particular, the metal nanoparticle compositions may be tailored to limit shrinkage during fusion, which may exceed 20% in other metal nanoparticle systems, and limit thermal expansion to reduce thermomechanical stress during operational hot-cold cycling. More specifically, metal nanoparticle compositions suitable for use in the present disclosure may contain larger, micron-size (micron-scale), highly thermally conductive particles (e.g., copper, silver, molybdenum, tungsten, aluminum, diamond, carbon nanotubes, graphene, and the like) while still being easily dispensed by various trench-filling techniques.

Such additives may decrease the coefficient of thermal expansion (CTE) of a monolithic metal body formed from copper nanoparticles down to about 11 ppm/° C., or even as low as 3 ppm/° C. in some cases, as compared to a value of 17 ppm/° C. typically found for bulk copper. These features greatly simplify PCB assembly and may provide overall product cost reduction while significantly enhancing performance. Once metal nanoparticle consolidation occurs, the resulting bulk metal binds the micron-scale additives together to form a monolithic metal body extending across a dimension of the insulating substrate of the PCB, thereby providing a conductive pathway across the substrate. The monolithic metal body may comprise a composite material depending on the nature of the micron-scale particles. Additional tailoring of a metal nanoparticle composition to promote dispensation and/or consolidation of the metal nanoparticles and to maximize conductivity may also be performed.

While it is not necessary that any steps are needed to promote adherence of the conductive material to the sidewalls of the one or more structures, in certain embodiments, adhesion of the monolithic metal body in the structure (i.e., one or more trenches, grooves, and/or vias) may be enhanced by plating a thin coating of a different metal upon sidewalls and bottoms of the one or more structures before filling each of the one or more structures with metal nanoparticles. In the case of filling the one or more structures with copper nanoparticles, plating of the one or more structures with tin may significantly improve adherence of the monolithic metal body to the sidewalls and bottom of the one or more structures. The tin is not believed to melt when processing the copper nanoparticles to form a monolithic metal body within each of the one or more structures. Without being bound by any theory or mechanism, a tin-copper intermetallic compound is believed to form following copper nanoparticle consolidation in a tin-coated trench or groove, wherein the tin-copper intermetallic compound may promote stability against thermal cycling stresses. The tin is believed to provide a CTE mediator that may be better matched with that of the substrate. Other metals that provide CTE matching and/or readily form alloys or intermetallic compounds with copper around the fusion temperature of copper nanoparticles (~200° C.) may also be suitable in this regard. Once the alloy or intermetallic compound forms, no additional melting occurs during subsequent heating operations. The tin-copper intermetallic compound or alternative substance may undergo thermal cycling multiple times without significantly decreasing adherence. Since only a thin tin layer needs to be deposited upon the sidewalls and bottom of the one or more structures, plating may be performed conventionally and much more rapidly than approaches for wholly filling the one or more structures with electrodeposited metal. Alternative coatings such as gallium, zinc and others may also be suitably used in the disclosure herein to promote adherence of a monolithic metal body to the sidewalls and bottom of the one or more structures.

Suitable conditions for electrodepositing tin will be familiar to one having ordinary skill in the art. In illustrative embodiments, electrodeposition of tin may take place by an electroless plating technique. Electroless plating of tin may be conducted by reacting a solution of a tin salt with a reducing agent such as borohydride, for example, within the one or more trenches or grooves. Other suitable conditions for electroplating tin may also be suitably used. The tin coating may have a thickness ranging from about 10 microns to about 250 microns, or about 5 microns to about 15 microns, or about 10 microns to about 50 microns, or about 0.5 microns to about 1 micron for example.

In one embodiment, when the conductive structure comprises one or more through-hole power vias or coins, the opening for the conductive structure (e.g., through-hole power via or coin) may be formed after the construction of the printed circuit has been completed, for example by punching, cutting (i.e., with a laser) or other suitable means for forming the opening for the conductive structure in the printed circuit board. In this instance, instead of a metal coating being applied to the sidewalls of the conductive structure, an electrically insulating material may be applied to electrically insulate the conductive structure from other conductive layers and features in the printed circuit board. This insulating layer may include, for example, an epoxy film or polymer adhesive that is curable at low temperature. The sidewalls of the opening for the conductive structure may first be coated with a thin layer of the insulating layer and then the opening is filled with the conductive material. In another embodiment, the insulating layer may comprise a polymer sleeve that is mechanically placed, cut to size, and then cured in place in the opening for the conductive structure prior to filling with the conductive material.

Nanoparticles exhibit a number of properties that can differ significantly from those of the corresponding bulk metal. One property of metal nanoparticles that can be of particular importance for processing according to the disclosure herein is nanoparticle fusion (consolidation) that occurs at the metal nanoparticles' fusion temperature. As used herein, the term “fusion temperature” refers to the temperature at which a metal nanoparticle liquefies, thereby giving the appearance of melting. As used herein, the terms “fusion” and “consolidation” synonymously refer to the coalescence or partial coalescence of metal nanoparticles with one another to form a larger mass, such as a monolithic metal body for filling the one or more structures with a material that is highly conductive. Accordingly, there is at least partial connectivity between the metal nanoparticles following heating above the fusion temperature. Following consolidation of the metal nanoparticles, the resulting nanoporosity may accommodate thermal stresses occurring during heat-up and cool-down. As shown, consolidated copper nanoparticles exhibit superior stress-strain behavior compared to other materials commonly used in PCB manufacturing. Moreover, nanoporosity in this range may afford ductility and deformation during extreme thermal cycling operations, thereby decreasing a risk of failure.

Upon decreasing in size, particularly below about 200 nm in equivalent spherical diameter, the temperature at which metal nanoparticles undergo liquefication drops dramatically from that of the corresponding bulk metal. For example, copper nanoparticles having a size of about 20 nm or less can have fusion temperatures of about 235° C. or below, or about 220° C. or below, or about 200° C. or below, or about 180° C. or below or as low as 155° C. in comparison to bulk copper's melting point of 1083° C. Thus, the consolidation of metal nanoparticles taking place at the fusion temperature can allow structures containing bulk metal to be fabricated at significantly lower processing temperatures than when working directly with the bulk metal itself as a starting material. Processing conditions for consolidating metal nanoparticles are typically within normal PCB manufacturing parameters of around 300° F. (150° C.), or even up to about 450° F. (232° C.), and 275-1500 psi.

Pressure is not necessarily required for metal nanoparticle fusion to take place. More dense monolithic metal bodies may be obtained by applying pressure when promoting metal nanoparticle consolidation. In the case of copper nanoparticles, for example, the fusion temperature is below the temperatures at which commonly used PCB substrates undergo melting or distortion. Thus, metal nanoparticles, such as copper nanoparticles, provide a suitable material for filling the one or more structures in the PCBs and forming a highly conductive monolithic block comprising bulk metal or a bulk metal composite without distorting the board or damaging other components on the board. Accordingly, the use of metal nanoparticles according to the disclosure herein does not require development of alternative fabrication lines or materials differing from those conventionally used in PCB manufacturing.

A number of scalable processes for producing bulk quantities of metal nanoparticles in a targeted size range have been developed. Most typically, such processes for producing metal nanoparticles take place by reducing a metal precursor in the presence of one or more surfactants. The metal nanoparticles can then be isolated and purified from the reaction mixture by common isolation techniques and processed into a formulation suitable for dispensation into the one or more structures.

Any suitable technique can be employed for forming the metal nanoparticles used in the disclosure herein. Particularly facile metal nanoparticle fabrication techniques are described in U.S. Pat. Nos. 7,736,414, 8,105,414, 8,192,866, 8,486,305, 8,834,747, 9,005,483, 9,095,898, and 9,700,940, each of which is incorporated herein by reference in its entirety. As described therein, metal nanoparticles can be fabricated in a narrow size range by reduction of a metal salt in a solvent in the presence of a suitable surfactant system, which can include one or more different surfactants. Further description of suitable surfactant systems follows below. Without being bound by any theory or mechanism, it is believed that the surfactant system can mediate the nucleation and growth of the metal nanoparticles, limit surface oxidation of the metal nanoparticles, and/or inhibit metal nanoparticles from extensively aggregating with one another prior to being at least partially fused together. Suitable organic solvents for solubilizing metal salts and forming metal nanoparticles can include, for example, formamide, N,N-dimethylformamide, dimethyl sulfoxide, dimethylpropylene urea, hexamethylphosphoramide, tetrahydrofuran, glyme, diglyme, triglyme, tetraglyme, proglyme, or polyglyme. Reducing agents suitable for reducing metal salts and promoting the formation of metal nanoparticles can include, for example, an alkali metal in the presence of a suitable catalyst (e.g., lithium naphthalide, sodium naphthalide, or potassium naphthalide) or borohydride reducing agents (e.g., sodium borohydride, lithium borohydride, potassium borohydride, or tetraalkylammonium borohydrides).

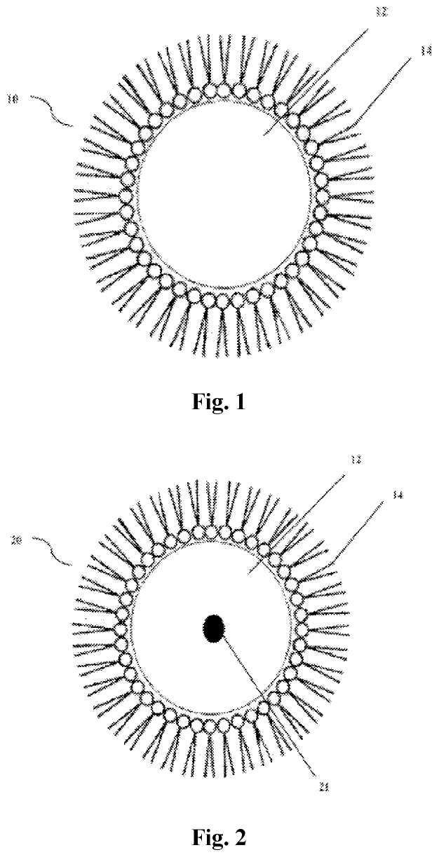

FIGS. 1 and 2 show diagrams of presumed structures of metal nanoparticles having a surfactant coating thereon. As shown in FIG. 1, metal nanoparticle 10 includes metallic core 12 and surfactant layer 14 overcoating metallic core 12. Surfactant layer 14 can contain any combination of surfactants, as described in more detail below. Metal nanoparticle 20, shown in FIG. 2, is similar to that depicted in FIG. 1, except metallic core 12 is grown about nucleus 21, which can be a metal that is the same as or different than that of metallic core 12. Because nucleus 21 is buried deep within metallic core 12 in metal nanoparticle 20 and is very small in size, it is not believed to significantly affect the overall nanoparticle properties. Nucleus 21 may comprise a salt or a metal, wherein the metal may be the same as or different than metallic core 12. In some embodiments, the nanoparticles can have an amorphous morphology.

As discussed above, the metal nanoparticles have a surfactant coating containing one or more surfactants upon their surface. The surfactant coating can be formed on the metal nanoparticles during their synthesis. The surfactant coating is generally lost during consolidation of the metal nanoparticles upon heating above the fusion temperature, which results in formation of a monolithic metal body within the one or more trenches or grooves, according to the embodiments of the present disclosure. Formation of a surfactant coating upon metal nanoparticles during their syntheses can desirably limit the ability of the metal nanoparticles to fuse to one another prematurely, limit agglomeration of the metal nanoparticles, and promote the formation of a population of metal nanoparticles having a narrow size distribution.

The properties of partially fused metal nanoparticles can be intermediate between those of the corresponding bulk metal and the original unfused metal nanoparticles. In some embodiments, fully dense (non-porous) bulk metal can be obtained following nanoparticle consolidation. Porosity values may range from 2-30% following consolidation, which may be tailored based upon a number of factors, including the type of surfactant(s) that are present and the consolidation conditions. In other embodiments, the bulk metal can have less than about 10% porosity, or less than about 20% porosity, or less than about 30% porosity in an amount above full densification (i.e., >0% porosity). Thus, in particular embodiments, the bulk metal resulting from metal nanoparticle consolidation may have a porosity ranging from about 2% to about 30%, or about 2% to about 5%, or about 5% to about 10%, or about 10% to about 15%, or about 15% to about 20%, or about 20% to about 25%, or about 25% to about 30%. In a particular example, consolidated copper nanoparticles may have a uniform porosity of about 12% and exhibit a thermal conductivity of 289 W/m K and consolidated copper nanoparticles may have a uniform porosity of about 3% and exhibit a thermal conductivity of 383 W/m·K. The nanoporosity may range from about 2% to about 15% (i.e., 85%-98% dense fused copper nanoparticles with closed pore nanoporosity having a pore size ranging from about 50 nm to about 500 nm, or about 100 nm to about 300 nm, or about 150 nm to about 250 nm). Nanoporosity in this range may afford ductility and stable deformation (flexibility) during extreme thermal cycling operations, thereby decreasing a risk of failure during PCB manufacture.

The types of metal nanoparticles suitable are not believed to be particularly limited. Suitable metal nanoparticles can include, but are not limited to, tin nanoparticles, copper nanoparticles, aluminum nanoparticles, palladium nanoparticles, silver nanoparticles, gold nanoparticles, iron nanoparticles, cobalt nanoparticles, nickel nanoparticles, titanium nanoparticles, zirconium nanoparticles, hafnium nanoparticles, tantalum nanoparticles, and the like. Micron-scale particles of these metals can be present in metal nanoparticle paste compositions containing the metal nanoparticles as well. Copper can be a particularly desirable metal for use in the embodiments of the present disclosure due to its low cost, strength, and excellent electrical and thermal conductivity values.

As discussed above, adherence of copper to at least the sidewalls and bottom of a trench or groove (or to the sidewalls of a through-hole power via or coin) may be enhanced through use of an electrodeposited coating, such as a coating comprising tin, as discussed further herein. Alternative coatings such as those comprising gallium, zinc and others may also be suitably used in this regard to promote adherence of a monolithic metal body to the surfaces of the one or more structures.

In various embodiments, the surfactant system present within the metal nanoparticles can include one or more surfactants, and differing properties of various surfactants can be used to tailor the properties of the metal nanoparticles. Factors that can be taken into account when selecting a surfactant or combination of surfactants for inclusion upon the metal nanoparticles can include, for example, ease of surfactant dissipation from the metal nanoparticles during nanoparticle fusion, nucleation and growth rates of the metal nanoparticles, the metal component of the metal nanoparticles, and the like.

In some embodiments, an amine surfactant or combination of amine surfactants, particularly aliphatic amines, can be present upon the metal nanoparticles. Amine surfactants can be particularly desirable for use in conjunction with copper nanoparticles. In some embodiments, two amine surfactants can be used in combination with one another. In other embodiments, three amine surfactants can be used in combination with one another. In more specific embodiments, a primary amine, a secondary amine, and a diamine chelating agent can be used in combination with one another. In still more specific embodiments, the three amine surfactants can include a long chain primary amine, a secondary amine, and a diamine having at least one tertiary alkyl group nitrogen substituent.

In some embodiments, the surfactant system can include a primary alkylamine. In some embodiments, the primary alkylamine can be a C₂-C₁₈ alkylamine. In some embodiments, the primary alkylamine can be a C₇-C₁₀ alkylamine. In other embodiments, a C₅-C₆ primary alkylamine can also be used. Without being bound by any theory or mechanism, the exact size of the primary alkylamine can be balanced between being long enough to provide an effective inverse micelle structure during synthesis versus having ready volatility and/or ease of handling during nanoparticle consolidation. For example, primary alkylamines with more than 18 carbons can also be suitable for use in the present embodiments, but they can be more difficult to handle because of their waxy character. C₇-C₁₀ primary alkylamines, in particular, can represent a good balance of desired properties for ease of use.

In some embodiments, the C₂-C₁₈ primary alkylamine can be n-hexylamine, n-heptylamine, n-octylamine, n-nonylamine, or n-decylamine, for example. While these are all straight chain primary alkylamines, branched chain primary alkylamines can also be used in other embodiments. For example, branched chain primary alkylamines such as, for example, 7-methyloctylamine, 2-methyloctylamine, or 7-methylnonylamine can be used. In some embodiments, such branched chain primary alkylamines can be sterically hindered where they are attached to the amine nitrogen atom. Non-limiting examples of such sterically hindered primary alkylamines can include, for example, t-octylamine, 2-methylpentan-2-amine, 2-methylhexan-2-amine, 2-methylheptan-2-amine, 3-ethyloctan-3-amine, 3-ethylheptan-3-amine, 3-ethylhexan-3-amine, and the like. Additional branching can also be present. Without being bound by any theory or mechanism, it is believed that primary alkylamines can serve as ligands in the metal coordination sphere but be readily dissociable therefrom during metal nanoparticle consolidation.

In some embodiments, the surfactant system can include a secondary amine. Secondary amines suitable for forming metal nanoparticles can include normal, branched, or cyclic C₄-C₁₂ alkyl groups bound to the amine nitrogen atom. In some embodiments, the branching can occur on a carbon atom bound to the amine nitrogen atom, thereby producing significant steric encumbrance at the nitrogen atom. Suitable secondary amines can include, without limitation, dihexylamine, diisobutylamine, di-t-butylamine, dineopentylamine, di-t-pentylamine, dicyclopentylamine, dicyclohexylamine, and the like. Secondary amines outside the C₄-C₁₂ range can also be used, but such secondary amines can have undesirable physical properties such as low boiling points or waxy consistencies that can complicate their handling.

In some embodiments, the surfactant system can include a chelating agent, particularly a diamine chelating agent. In some embodiments, one or both of the nitrogen atoms of the diamine chelating agent can be substituted with one or two alkyl groups. When two alkyl groups are present on the same nitrogen atom, they can be the same or different. Further, when both nitrogen atoms are substituted, the same or different alkyl groups can be present. In some embodiments, the alkyl groups can be C₁-C₆ alkyl groups. In other embodiments, the alkyl groups can be C₁-C₄ alkyl groups or C₃-C₆ alkyl groups. In some embodiments, C₃ or higher alkyl groups can be straight or have branched chains. In some embodiments, C₃ or higher alkyl groups can be cyclic. Without being bound by any theory or mechanism, it is believed that diamine chelating agents can facilitate metal nanoparticle formation by promoting nanoparticle nucleation.

In some embodiments, suitable diamine chelating agents can include N,N′-dialkylethylenediamines, particularly C1-C4 N,N′-dialkylethylenediamines and N,N,N′,N′-tetraalkylethylenediamines, particularly C1-C4 N,N,N′,N′-tetraalkylethylenediamines. The corresponding methylenediamine, propylenediamine, butylenediamine, pentylenediamine or hexylenediamine derivatives can also be used. The alkyl groups can be the same or different. C₁-C₄ alkyl groups that can be present include, for example, methyl, ethyl, propyl, and butyl groups, or branched alkyl groups such as isopropyl, isobutyl, s-butyl, and t-butyl groups. Illustrative N,N′-dialkylethylenediamines that can be suitable for inclusion upon metal nanoparticles include, for example, N,N′-di-t-butylethylenediamine, N,N′-diisopropylethylenediamine, and the like. Illustrative N,N,N′,N′-tetraalkylethylenediamines that can be suitable for use in forming metal nanoparticles include, for example, N,N,N′,N′-tetramethylethylenediamine, N,N,N′,N′-tetraethylethylenediamine, and the like.

Surfactants other than aliphatic amines can also be present in the surfactant system. In this regard, suitable surfactants can include, for example, pyridines, aromatic amines, phosphines, thiols, or any combination thereof. These surfactants can be used in combination with an aliphatic amine, including those described above, or they can be used in a surfactant system in which an aliphatic amine is not present.

Suitable aromatic amines can have a formula of ArNR₁R₂, where Ar is a substituted or unsubstituted aryl group and R₁ and R₂ are the same or different. R₁ and R₂ can be independently selected from H or an alkyl or aryl group containing from 1 to about 16 carbon atoms. Illustrative aromatic amines that can be suitable for use in forming metal nanoparticles include, for example, aniline, toluidine, anisidine, N,N-dimethylaniline, N,N-diethylaniline, and the like. Other aromatic amines that can be used in conjunction with metal nanoparticles can be envisioned by one having ordinary skill in the art.

Suitable pyridines can include both pyridine and its derivatives. Illustrative pyridines that can be suitable for use inclusion upon metal nanoparticles include, for example, pyridine, 2-methylpyridine, 2,6-dimethylpyridine, collidine, pyridazine, and the like. Chelating pyridines such as bipyridyl chelating agents may also be used. Other pyridines that can be used in conjunction with metal nanoparticles can be envisioned by one having ordinary skill in the art.

Suitable phosphines can have a formula of PR₃, where R is an alkyl or aryl group containing from 1 to about 16 carbon atoms. The alkyl or aryl groups attached to the phosphorus center can be the same or different. Illustrative phosphines that can be present upon metal nanoparticles include, for example, trimethylphosphine, triethylphosphine, tributylphosphine, tri-t-butylphosphine, trioctylphosphine, triphenylphosphine, and the like. Phosphine oxides can also be used in a like manner. In some embodiments, surfactants that contain two or more phosphine groups configured for forming a chelate ring can also be used. Illustrative chelating phosphines can include 1,2-bisphosphines, 1,3-bisphosphines, and bis-phosphines such as BINAP, for example. Other phosphines that can be used in conjunction with metal nanoparticles can be envisioned by one having ordinary skill in the art.

Suitable thiols can have a formula of RSH, where R is an alkyl or aryl group having from about 4 to about 16 carbon atoms. Illustrative thiols that can present upon metal nanoparticles include, for example, butanethiol, 2-methyl-2-propanethiol, hexanethiol, octanethiol, benzenethiol, and the like. In some embodiments, surfactants that contain two or more thiol groups configured for forming a chelate ring can also be used. Illustrative chelating thiols can include, for example, 1,2-dithiols (e.g., 1,2-ethanethiol) and 1,3-dithiols (e.g., 1,3-propanethiol). Other thiols that can be used in conjunction with metal nanoparticles can be envisioned by one having ordinary skill in the art.

A distinguishing feature of metal nanoparticles is their low fusion temperature, which may facilitate filling of the one or more structures to establish an effective thermal conduction pathway therein, according to the various embodiments of the present disclosure. In order to facilitate their disposition and formation of a monolithic metal body within each of the one or more structures, the metal nanoparticles may be incorporated in a paste or similar formulation suitable for controlled introduction into the one or more structures.

Metal nanoparticle paste compositions or similar formulations can be prepared by dispersing as-produced or as-isolated metal nanoparticles in an organic matrix containing one or more organic solvents and various other optional components. As used herein, the terms “nanoparticle paste formulation,” “nanoparticle paste composition” and grammatical equivalents thereof are used interchangeably and refer synonymously to a fluid composition containing dispersed metal nanoparticles that is suitable for dispensation using a desired technique. Use of the term “paste” does not necessarily imply an adhesive function of the paste alone. Through judicious choice of the organic solvent(s) and other additives, the loading of metal nanoparticles and the like, ready dispensation of the metal nanoparticles within one or more structures may be promoted.

Cracking can sometimes occur during consolidation of the metal nanoparticles. One way in which the nanoparticle pastes of the present disclosure can promote a decreased degree of cracking and void formation following metal nanoparticle consolidation is by maintaining a high solids content. More particularly, in some embodiments, the paste compositions can contain at least about 30 wt. % metal nanoparticles, particularly about 30 wt. % to about 98 wt. % metal nanoparticles by weight of the paste composition, or about 50% to about 95% metal nanoparticles by weight of the paste composition, or about 70% to about 98% metal nanoparticles by weight of the paste composition. Moreover, in some embodiments, small amounts (e.g., about 0.01% to about 15% or about 35% or about 60% by weight of the paste composition) of micron-scale particles, particularly micron-scale metal particles, can be present in addition to the metal nanoparticles. Such micron-scale metal particles can desirably promote the fusion of metal nanoparticles into a contiguous mass (monolithic metal body) and further reduce the incidence of cracking. Instead of being liquefied and undergoing direct consolidation as is the case for the metal nanoparticles, the micron-scale metal particles can simply become joined together upon being contacted with liquefied metal nanoparticles that have been raised above their fusion temperature. These factors can reduce the porosity that results after fusing the metal nanoparticles together. The micron-scale metal particles can contain the same or different metals than the metal nanoparticles, and suitable metals for the micron-scale metal particles can include, for example, copper, silver, gold, aluminum, tin, and the like. Micron-scale graphite particles may also be included, in some embodiments. Carbon nanotubes, diamond particles, and/or graphene may be included, in some embodiments. Carbonaceous additives may increase the thermal conductivity resulting after metal nanoparticle consolidation takes place, according to some embodiments. Any of the foregoing micron-scale particles may serve as crack deflectors to limit propagation of cracks during use, thereby increasing mechanical strength.

Decreased cracking and void formation during metal nanoparticle consolidation can also be promoted by judicious choice of the solvent(s) forming the organic matrix. A tailored combination of organic solvents can desirably decrease the incidence of cracking and void formation. More particularly, an organic matrix containing one or more hydrocarbons (saturated, monounsaturated, polyunsaturated (2 or more double bonds) or aromatic), one or more alcohols, one or more amines, and one or more organic acids can be especially effective for this purpose. One or more esters and/or one or more anhydrides may be included, in some embodiments. Alkanolamines, such as ethanolamine, may also be present in some instances. Without being bound by any theory or mechanism, it is believed that this combination of organic solvents can facilitate the removal and sequestration of surfactant molecules surrounding the metal nanoparticles during consolidation, such that the metal nanoparticles can more easily fuse together with one another. More particularly, it is believed that hydrocarbon and alcohol solvents can passively solubilize surfactant molecules released from the metal nanoparticles by Brownian motion and reduce their ability to become re-attached thereto. In concert with the passive solubilization of surfactant molecules, amine and organic acid solvents can actively sequester the surfactant molecules through a chemical interaction such that they are no longer available for recombination with the metal nanoparticles.

Further tailoring of the solvent composition can be performed to reduce the suddenness of volume contraction that takes place during surfactant removal and metal nanoparticle consolidation. Specifically, more than one member of each class of organic solvent (i.e., hydrocarbons, alcohols, amines, and organic acids), optionally in combination with one or more alkanolamines, esters or anhydrides, can be present in the organic matrix, where the members of each class have boiling points that are separated from one another by a set degree. For example, in some embodiments, the various members of each class can have boiling points that are separated from one another by about 10° C. to about 50° C. By using such a solvent mixture, sudden volume changes due to rapid loss of solvent can be minimized during metal nanoparticle consolidation, since the various components of the solvent mixture can be removed gradually over a broad range of boiling points (e.g., about 50° C. to about 200° C. or more).

In various embodiments, at least some of the one or more organic solvents can have a boiling point of about 100° C. or greater. In other various embodiments, at least some of the one or more organic solvents can have a boiling point of about 200° C. or greater. In some or other embodiments, the one or more organic solvents can have boiling points ranging between about 50° C. and about 200° C., or between about 50° C. and about 250° C., or between about 50° C. and about 300° C., or between about 50° C. and about 350° C. Use of high boiling organic solvents can desirably increase the pot life of the metal nanoparticle paste compositions and limit the rapid loss of solvent, which can otherwise lead to cracking and void formation during nanoparticle consolidation. In some embodiments, at least one of the organic solvents can have a boiling point that is higher than the boiling point(s) of the surfactant(s) associated with the metal nanoparticles. Accordingly, surfactant(s) can be removed from the metal nanoparticles by evaporation before removal of the organic solvent(s) takes place.

In some embodiments, the organic matrix can contain one or more alcohols, which may be C₂-C₁₂, C₄-C₁₂ or C₇-C₁₂ in more particular embodiments. In various embodiments, the alcohols can include monohydric alcohols, diols, or triols. One or more glycol ethers (e.g., diethylene glycol and triethylene glycol), alkanolamines (e.g., ethanolamine, triethanolamine, and the like), or any combination thereof may be present in certain embodiments, which may be present alone or in combination with other alcohols. Various glymes may be present with the one or more alcohols in some embodiments. In some embodiments, one or more hydrocarbons can be present in combination with one or more alcohols. As discussed above, it is believed that alcohol (and optionally glymes and alkanolamines) and hydrocarbon solvents can passively promote the solubilization of surfactants as they are removed from the metal nanoparticles by Brownian motion and limit their re-association with the metal nanoparticles. Moreover, hydrocarbon and alcohol solvents only weakly coordinate with metal nanoparticles, so they do not simply replace the displaced surfactants in the nanoparticle coordination sphere. Illustrative but non-limiting examples of alcohol and hydrocarbon solvents that can be present include, for example, light aromatic petroleum distillate (CAS 64742-95-6), hydrotreated light petroleum distillates (CAS 64742-47-8), tripropyleneglycol methyl ether, ligroin (CAS 68551-17-7, a mixture of C₁₀-C₁₃ alkanes), diisopropyleneglycol monomethyl ether, diethyleneglycol diethyl ether, 2-propanol, 2-butanol, t-butanol, 1-hexanol, 2-(2-butoxyethoxy) ethanol, and terpineol. In some embodiments, polyketone solvents can be used in a like manner.

In some embodiments, the organic matrix can contain one or more amines and one or more organic acids. In some embodiments, the one or more amines and one or more organic acids can be present in an organic matrix that also includes one or more hydrocarbons and one or more alcohols. As described herein, it is believed that amines and organic acids can actively sequester surfactants that have been passively solubilized by hydrocarbon and alcohol solvents, thereby making the surfactants unavailable for re-association with the metal nanoparticles. Thus, an organic solvent that contains a combination of one or more hydrocarbons, one or more alcohols, one or more amines, and one or more organic acids can provide synergistic benefits for promoting the consolidation of metal nanoparticles. Illustrative but non-limiting examples of amine solvents that can be present include, for example, tallowamine (CAS 61790-33-8), alkyl (C₈-C₁₈) unsaturated amines (CAS 68037-94-5), di(hydrogenated tallow) amine (CAS 61789-79-5), dialkyl (C₅-C₂₀) amines (CAS 68526-63-6), alkyl (C₁₀-C₁₆) dimethyl amine (CAS 67700-98-5), alkyl (C₁₄-C₁₈) dimethyl amine (CAS 68037-93-4), dihydrogenated tallowmethyl amine (CAS 61788-63-4), and trialkyl (C₆-C₁₂) amines (CAS 68038-01-7). Illustrative but non-limiting examples of organic acid solvents that can be present in the nanoparticle paste compositions include, for example, octanoic acid, nonanoic acid, decanoic acid, caprylic acid, pelargonic acid, undecylic acid, lauric acid, tridecylic acid, myristic acid, pentadecanoic acid, palmitic acid, margaric acid, stearic acid, nonadecylic acid, α-linolenic acid, stearidonic acid, oleic acid, and linoleic acid.

In some embodiments, the organic matrix can include more than one hydrocarbon, more than one alcohol, optionally more than one glyme (glycol ether), more than one amine, and more than one organic acid. For example, in some embodiments, each class of organic solvent can have two or more members, or three or more members, or four or more members, or five or more members, or six or more members, or seven or more members, or eight or more members, or nine or more members, or ten or more members. Moreover, the number of members in each class of organic solvent can be the same or different. Particular benefits of using multiple members of each class of organic solvent are described hereinafter.

One particular advantage of using multiple members within each class of organic solvent can include the ability to provide a wide spread of boiling points in the metal nanoparticle paste compositions. By providing a wide spread of boiling points, the organic solvents can be removed gradually as the temperature rises while affecting metal nanoparticle consolidation, thereby limiting volume contraction and disfavoring cracking. By gradually removing the organic solvent in this manner, less temperature control may be needed to affect slow solvent removal than if a single solvent with a narrow boiling point range was used.

In some embodiments, the members within each class of organic solvent can have a window of boiling points ranging between about 50° C. and about 200° C., or between about 50° C. and about 250° C., or between about 100° C. and about 200° C., or between about 100° C. and about 250° C., or between about 150° C. and about 300° C., or between about 150° C. and about 350° C. In more particular embodiments, the various members of each class of organic solvent can each have boiling points that are separated from one another by at least about 10° C., specifically about 20° C. to about 50° C. More specifically, in some embodiments, each hydrocarbon can have a boiling point that differs by about 20° C. to about 50° C. from other hydrocarbons in the organic matrix, each alcohol can have a boiling point that differs by about 20° C. to about 50° C. from other alcohols in the organic matrix, each amine can have a boiling point that differs by about 20° C. to about 50° C. from other amines in the organic matrix, and each organic acid can have a boiling point that differs by about 20° C. to about 50° C. from other organic acids in the organic matrix. The more members of each class of organic solvent that are present, the smaller the differences become between the boiling points. By having smaller differences between the boiling points, solvent removal can be made more continual, thereby limiting the degree of volume contraction that occurs at each stage. A reduced degree of cracking can occur when four to five or more members of each class of organic solvent are present (e.g., four or more hydrocarbons, four or more alcohols, four or more amines, and four or more organic acids; or five or more hydrocarbons, five or more alcohols, five or more amines, and five or more organic acids), each having boiling points that are separated from one another within the above range.

In various embodiments, the metal nanoparticles used in the metal nanoparticle paste compositions can be about 100 nm or less in size or 75 nm or less in size or 50 nm or less in size or even 20 nm or less in size. In other various embodiments, metal nanoparticles may be up to about 75 nm in size or up to 100 nm in size or up to 300 nm in size. As discussed above, metal nanoparticles in this size range have fusion temperatures that are significantly lower than those of the corresponding bulk metal and, as a result, readily undergo consolidation with one another. In some embodiments, metal nanoparticles that are about 100 nm or less in size or 20 nm or less in size can have a fusion temperature of about 220° C. or below (e.g., a fusion temperature in the range of about 140° C. to about 220° C.) or about 200° C. or below, or about 175 C or below or as low as 155 C, which can provide advantages that are noted above. In some embodiments, at least a portion of the metal nanoparticles can be about 10 nm or less in size, or about 5 nm or less in size. In more specific embodiments, at least a portion of the metal nanoparticles can range from about 1 nm in size to about 20 nm in size, or from about 1 nm in size and about 10 nm in size, or from about 1 nm in size to about 5 nm in size, or from about 3 nm in size to about 7 nm in size, or from about 5 nm in size to about 20 nm in size.

In some embodiments, substantially all of the metal nanoparticles can reside within these size ranges. In some embodiments, larger metal nanoparticles can be combined in the metal nanoparticle paste compositions with metal nanoparticles that are about 20 nm in size or less. For example, in some embodiments, metal nanoparticles ranging from about 1 nm to about 10 nm in size can be combined with metal nanoparticles that range from about 25 nm to about 50 nm in size, or with metal nanoparticles that range from about 25 nm to about 100 nm in size or about 75 nm to about 150 nm in size or about 125 to about 250 nm in size or about 50 nm to about 300 nm in size. As further discussed below, micron-scale metal particles and/or nanoscale particles can also be included in the metal nanoparticle paste compositions in some embodiments. Although larger metal nanoparticles and micron-scale metal particles may not be liquefiable at the low temperatures of their smaller counterparts, they can still become consolidated upon contacting the smaller metal nanoparticles that have been liquefied at or above their fusion temperature, as generally discussed above.

In addition to metal nanoparticles and organic solvents, other additives can also be present in the metal nanoparticle paste compositions. Such additional additives can include, for example, rheology control aids, thickening agents, micron-scale conductive additives, nanoscale conductive additives, and any combination thereof. Chemical additives can also be present. As discussed hereinafter, the inclusion of micron-scale conductive additives, such as micron-scale metal particles, can be particularly advantageous. Nanoscale or micron-scale diamond or other thermally conductive additives may be desirable to include in some instances for promoting more efficient heat transfer.

In some embodiments, the paste compositions can contain about 0.01% to about 15% micron-scale metal particles by weight, or about 1% to about 10% micron-scale metal particles by weight, or about 1% to about 5% micron-scale metal particles by weight, or about 0.1% to about 35% micron-scale metal particles by weight or about 5% to about 51% by weight or about 15% to about 60% by weight. Inclusion of micron-scale metal particles in the metal nanoparticle paste compositions can desirably reduce the incidence of cracking that occurs during consolidation of the metal nanoparticles when forming a monolithic metal body in each of the one or more structures. Without being bound by any theory or mechanism, it is believed that the micron-scale metal particles can become consolidated with one another as the metal nanoparticles are liquefied and form a transient liquid coating upon the surface of the micron-scale metal particles. In some embodiments, the micron-scale metal particles can range from about 500 nm to about 100 microns in size in at least one dimension, or from about 500 nm to about 10 microns in size in at least one dimension, or from about 100 nm to about 5 microns in size in at least one dimension, or from about 100 nm to about 10 microns in size in at least one dimension, or from about 100 nm to about 1 micron in size in at least one dimension, or from about 1 micron to about 10 microns in size in at least one dimension, or from about 5 microns to about 10 microns in size in at least one dimension, or from about 1 micron to about 100 microns in size in at least one dimension. The micron-scale metal particles can contain the same metal as the metal nanoparticles or contain a different metal. Thus, metal alloys can be fabricated by including micron-scale metal particles in the paste compositions with a metal differing from that of the metal nanoparticles. Metal alloys may also be formed by combining different types of metal nanoparticles with one another. Suitable micron-scale metal particles can include, for example, Cu, Ni, Al, Fe, Co, Mo, Ag, Zn, Sn, Au, Pd, Pt, Ru, Mn, Cr, Ti, V, Mg or Ca particles. Non-metal particles such as, for example, Si and B micron-scale particles can be used in a like manner. In some embodiments, the micron-scale metal particles can be in the form of metal flakes, such as high aspect ratio copper flakes. Thus, in some embodiments, the metal nanoparticle paste compositions described herein can contain a mixture of copper nanoparticles and high aspect ratio copper flakes or another type of micron-scale copper particles. Specifically, in some embodiments, the metal nanoparticle paste compositions can contain about 30 wt. % to about 90 wt. % copper nanoparticles and about 0.01% to about 15% or 1 wt. % to 35 wt. % or about 30 wt. % to about 90 wt. % high aspect ratio copper flakes of varying sizes and aspect ratios.

Other micron-scale metal particles that can be used equivalently to high aspect ratio metal flakes include, for example, metal nanowires and other high aspect ratio particles, which can be up to about 300 microns in length. The ratio of metal nanoparticles to metal nanowires may range between about 10:1 to about 40:1, according to various embodiments. Suitable nanowires may have a length of about 5 microns to about 50 microns, and a diameter of about 100 nm to about 200 nm, for example.

In some embodiments, nanoscale conductive additives can also be present in the metal nanoparticle paste compositions. These additives can desirably provide further structural stabilization and reduce shrinkage during metal nanoparticle consolidation. Moreover, inclusion of nanoscale conductive additives can increase electrical and thermal conductivity values that can approach or even exceed that of the corresponding bulk metal following nanoparticle consolidation, which can be desirable for promoting heat transfer according to the disclosure herein. In some embodiments, the nanoscale conductive additives can have a size in at least one dimension ranging from about 1 micron to about 100 microns or ranging from about 1 micron to about 300 microns. Suitable nanoscale conductive additives can include, for example, carbon nanotubes, graphene, nanodiamond, and the like. When present, the metal nanoparticle paste compositions can contain about 1% to about 20% or about 1% to about 10% nanoscale conductive additives by weight, or about 1% to about 5% nanoscale conductive additives by weight, or about 5% to about 15% conductive additives by weight.

Additional substances that can also optionally be present in the metal nanoparticle paste compositions include, for example, flame retardants, UV protective agents, antioxidants, carbon black, graphite, fiber materials (e.g., chopped carbon fiber materials), diamond, and the like.

In some more specific embodiments, suitable nanoparticle paste compositions may further comprise diamond particles. A suitable size of diamond particles may be dictated by the size of the one or more structures to be filled. In general, diamond particles smaller in size than the diameter of the one or more structures may be selected so that the diamond particles can successfully enter the one or more structures. Moreover, the diamond particles may be sized as large as possible, taking into account the diameter of the one or more structures to limit grain boundaries that need to be crossed by phonons during heat transfer. The size of the diamond particles may remain sufficiently small such that dispensability of the metal nanoparticle paste composition is not compromised.

In still more specific embodiments, diamond particles suitable for use in the metal nanoparticle paste compositions may have a size ranging from about 1 micron to about 1000 microns, which can provide for good particle dispersion and acceptable paste dispensability. Diamond particles having a size ranging from about 200 microns to about 250 microns can represent a good compromise between providing effective dispersion and a minimized grain boundary for discouraging phonon scattering. Other suitable size ranges for the diamond particles can range from about 25 microns to about 150 microns, or about 50 microns to about 250 microns, or from about 100 microns to about 250 microns, or from about 100 microns to about 200 microns, or from about 150 microns to about 250 microns.

Nanoparticle paste compositions suitable for use in filling the one or more structures can be formulated using any of the metal nanoparticle paste compositions described hereinabove. In addition, according to some embodiments, multiple metals may be present in the metal nanoparticle paste compositions. In some or other embodiments, suitable metal nanoparticle paste compositions can include a mixture of metal nanoparticles, other nano-sized particles (i.e., particles having a dimension of about 100 nm or less), and/or micron-scale particles, including micron-scale metal particles. The metal nanoparticle paste compositions may comprise copper nanoparticles, according to more specific embodiments.

In various embodiments of the present disclosure, new or previously existing structures (i.e., trenches, grooves, vias, embedded conduits, etc.) in a circuit board (e.g., a PCB) may be filled with metal nanoparticles, which undergo subsequent consolidation to form a monolithic metal body in each of the one or more structures. The metal nanoparticles may be contained within a metal nanoparticle paste composition, such as a metal nanoparticle paste composition comprising copper nanoparticles. The metal nanoparticle paste composition is subsequently processed to promote at least partial consolidation of the metal nanoparticles within each of the one or more structures to form a monolithic metal body (a continuous mass of bulk metal) that fills each of the one or more structures. For example, according to various embodiments, the metal nanoparticles may be heated at or above the fusion temperature while located within the one or more structures to form the monolithic metal body therein. Alternately, pressure may be applied to promote metal nanoparticle consolidation within the one or more structures.

Moreover, adherence of a monolithic metal body to the sidewalls and bottom of the one or more structures may be enhanced by depositing a coating upon the sidewalls and/or bottom of each of the one or more structures prior to filling each of the one or more structures with the metal nanoparticle paste composition. In the case of a metal nanoparticle paste composition comprising copper nanoparticles, the resulting monolithic metal body may be robustly adhered to the sidewalls and/or bottom of the one or more structures when a tin coating is previously applied thereto. An intermetallic compound may be formed from a reaction between the coating and the metal nanoparticles at an interface between the monolithic metal body and the sidewalls and/or bottom of the one or more structures.

Structures such as trenches, grooves, through-hole power vias, and coins, are easily integrated into a PCB and may be drilled out or machined after initial assembly. The size range of the one or more structures that may be filled with metal nanoparticles according to the present disclosure is not considered to be particularly limited and may range from micron-sized up to sizes larger than one millimeter or more. According to more specific embodiments, the one or more structures can range in size (cross-sectional diameter) from about 100 microns up to about 30 mm or 50 mm. In still more specific embodiments, the one or more structures can range from about 1 mm to about 10 mm, or from 1 mm to about 8 mm, or from about 1 mm to about 5 mm, or from about 2 mm to about 5 mm, or from about 3 mm to about 10 mm, or from about 2 mm to about 15 mm, or from about 3 mm to about 15 mm. In some embodiments, at least a portion of the one or more structures may be about 5 mm or less in size. In some or other embodiments, at least a portion of the one or more structures may be about 2 mm to about 10 mm in size, or about 3 mm to about 10 mm in size, or about 4 mm to about 12 mm in size. The size(s) of the one or more structures may dictate to some degree the manner in which they are filled with a metal nanoparticle paste composition, such as a copper nanoparticle paste composition.

For example, in the case of larger trenches or grooves, particularly trenches and grooves about 1 mm or larger in size, inclusion of a tin coating upon the sidewalls and bottom of the trenches or grooves may be particularly desirable to limit separation of the monolithic metal body from the sidewalls and bottom of the trench or groove during use. Alternative coatings such as gallium, zinc and others may also be suitably used in this regard. Alternatively, as discussed above, through-hole power vias or coins may be provided with an electrically insulating layer to isolate the conductive structure from conductive layers and other features of the printed circuit board. Trench thicknesses (depths) may range from about 0.5 mm to about 1 cm, or about 1 mm to about 2 mm, or about 1 mm to about 5 mm. In addition, as discussed above, a final finish of gold, silver, or an alloy thereof may be applied to the top of the conducive trench or groove by a suitable means such as electroless plating or electroplating. Overall cross-section of the narrow side of the trench or groove may be within a range of about 16 mm² to about 125 mm².

In the case of through-hole power vias and coins, the through-hole power via or coin extends across the entire width of the printed circuit board from a top surface of the printed circuit board to the bottom surface may have a length of between about 500 microns and about 3 cm, or between about 1,000 microns and about 2.5 cm and a width of between about 50 microns and about 30 mm, or about 100 microns and about 30 mm or between about 500 microns and about 30 mm, or between about 1,000 microns and about 25 mm, or between about 5 mm and about 25 mm.

In addition, the number of the one or more structures in the printed circuit board may also vary depending on the power needs of the printed circuit board assembly, size of the board, orientation and configuration of the board, and other factors. Thus, the number of the one or more structures contained in the printed circuit board may be one or more, or at least 2, or at least 3, or at least 4, or more depending on the configuration.

Suitable structures, such as trenches and grooves, may have any cross-sectional profile as they extend laterally through the PCB. For example, as described above, suitable trench or groove cross-sectional profiles include, but are not limited to, square, rectangular, triangular, ovular, or other regular or irregular geometric shapes. The cross-sectional profile of the trenches or grooves may be substantially equal in size upon both faces of the PCB, or the cross-sectional profiles may differ in size, according to some embodiments.

Alternatively, as discussed above, structures, such as through-hole power vias and coins may have various cross-sectional profiles as they extend through the thickness of the board, i.e., from a top surface to a bottom surface of the board. In one embodiment, more than one through-hole power via or coin is disposed in the printed circuit board. In another embodiment two or more through-hole power vias or coins are disposed in the printed circuit board, and the two or more through-hole power vias or coins may be of substantially the same cross-sectional size and configuration or may exhibit a different cross-sectional size and/or configuration.

The PCBs and one or more structures incorporated therein may be single-layer or multi-layer, according to various embodiments. Multi-layer PCBs can contain individual layers that are laminated together to define the one or more structures and other board features. Both single-layer and multi-layer PCBs may be formed initially without the one or more structures being present, in which case the one or more structures may then be drilled or machined out after fabrication of the board (single- or multi-layer PCB) is complete.

Encapsulation in the form of conformal coatings or masking materials, for example, may be applied upon an outer surface of the PCB after fabrication thereof to provide further protection of exposed metal against oxidation. For example, conformal coatings or masking materials may overcoat the one or more structures filled with a monolithic metal body to inhibit formation of copper oxide.

The resulting printed circuit board structure with the conductive one or more contained therein can be operatively connected to an external power supply as described above by means of the conductive wires or other similar means.

### Additional Embodiments

Clause 1: A printed circuit board assembly comprising:
a. a printed circuit board, wherein the at least one printed circuit board comprises at least one insulating layer;
b. one or more structures formed in the printed circuit board, wherein the one or more structures extend substantially across a dimension of the printed circuit board and are at least substantially filled with a conductive material to form a conductive structure;
   wherein each of the one or more conductive structures are configured to transmit direct current across the dimension of the printed circuit board.
      Clause 2: The printed circuit board assembly according to Clause 1, wherein the conductive material comprises a monolithic block of bulk metal formed from a consolidation of a metal nanoparticle paste composition.
      Clause 3: The printed circuit board assembly according to Clause 2, wherein the monolithic block of bulk metal is a monolithic block of copper formed from the consolidation of a copper nanoparticle paste composition.
      Clause 4: The printed circuit board assembly according to Clause 2 or Clause 3, wherein the metal nanoparticle paste composition is formulated to limit shrinkage during consolidation of the metal nanoparticle composition.
      Clause 5: The printed circuit board assembly according to Clause 2 or Clause 3, wherein during consolidation, the metal nanoparticle paste composition forms the monolithic metal body that fills each of the one or more structures, wherein the monolithic metal body has a uniform nanoporosity ranging from about 2% to about 30%.
      Clause 6: The printed circuit board assembly according to any of Clauses 1 to 5, wherein at least some of the one or more structures have a depth of between about 150 microns and about 3 mm, preferably about 250 microns and about 2 mm, more preferably about 500 microns and about 3 mm.
      Clause 7: The printed circuit board assembly according to any of Clauses 1 to 6, wherein at least some of the one or more structures have a width of between about 100 microns and about 30 mm, more preferably about 500 microns and about 25 mm.
      Clause 8: The printed circuit board assembly according to any of Clause 1 to 7, further comprising a conductive wire disposed within at least a portion of the conductive material and extending out of the printed circuit board, wherein the wire is connectable to an external device.
      Clause 9: The printed circuit board assembly according to Clause 8, wherein the external device is operatively connected to a source of power for transmitting current into and through the printed circuit board, preferably wherein the source of power comprises a power cord.
      Clause 10: The printed circuit board assembly according to any of Clauses 1 to 9, wherein the one or more structures are selected from the group consisting of trenches, grooves, conduits, through-hole power vias, coins, fully or partially embedded wires, fully or partially embedded cables, and combinations of any of the foregoing.
      Clause 11: The printed circuit board assembly according to Clause 10, wherein the one or more structures comprises one or more conductive trenches or grooves, wherein the one or more conductive trenches or grooves further comprise one or more bends or branches.
      Clause 12: The printed circuit board assembly according to Clause 11, wherein the one or more bends or branches extend from the one or more trenches or grooves to one or more edges of the printed circuit board.
      Clause 13: The printed circuit board assembly according to Clause 11, wherein the one or more bends or branches form an angle with the one or more trenches or grooves, wherein angle between the at least one or more bend and the trench or groove is between about 20 degrees to about 90 degrees, more preferably about 30 degrees to about 80 degrees, more preferably about 40 degrees to about 70 degrees.
      Clause 14: The printed circuit board assembly according to Clause 10, wherein each of the one or more structures has a trapezoidal cross-sectional shape.
      Clause 15: The printed circuit board assembly according to Clause 14, wherein the trapezoidal cross sectional shape is wider at the top of the at least one trench and smaller at the bottom of the at least one trench or groove.
      Clause 16: The printed circuit board assembly according to Clause 14, wherein each of the one or more structures has substantially the same cross-sectional shape across the entire length of the each of the one or more structures.
      Clause 17: The printed circuit board assembly according to Clause 1, further comprising one or more structures formed in a second face of the at least one printed circuit board, wherein the one or more structures extend substantially across a dimension of the printed circuit board, wherein the one or more structures are at least substantially filled with a conductive material.
      Clause 18: The printed circuit board assembly according to Clause 10, wherein the one or more structures comprise one or more through-hole power vias and/or one or more coins, each of the one or more through-hole power vias and/or coins extending from a first lateral surface to a second lateral surface of the printed circuit board.
      Clause 19: The printed circuit board assembly according to Clause 18, wherein each of the one or more through-hole power vias and/or one coins has a cross-sectional shape selected from the group consisting of circle, oval, multi-sided polygon, square, and rectangle
      Clause 20: The printed circuit board assembly according to Clause 18 or Clause 19, wherein each of the one or more through-hole power vias and/or one or more coins is operatively connected to a power source for transmitting current into and through the printed circuit board.
      Clause 21: The printed circuit board assembly according to any of Clauses 18 to 20, wherein the printed circuit board assembly is operatively connected to a heat dissipation device such as a heat pipe, oscillating heat pipe, heat sink, thermal ground plane or other suitable device for dissipating heat.
      Clause 22: A method comprising:
a. forming one or more structures in a printed circuit board, wherein the printed circuit board comprises at least one insulating layer;
b. filling each of the one or more structures with a conductive material to form one or more conductive structures, wherein the conductive material comprises a metal nanoparticle paste composition; and
c. consolidating the conductive material using heat and/or pressure to form a monolithic metal body within each of the one or more structures, wherein the monolithic metal body at least substantially fills each of the one or more structures;
   wherein the monolithic metal body transmits direct current across the printed circuit board through the one or more conductive structures when connected to a power source.
      Clause 23: The method according to Clause 22, wherein the metal nanoparticle paste composition comprises copper nanoparticles and the monolithic metal body is a monolithic copper body.
      Clause 24: The method according to Clause 23, wherein monolithic copper body has a conductivity of at least 50% International Annealed Copper Standard (% IACS), preferably at least 60% IACS, or at least 70% IACS, or between 60 and 95% IACS.
      Clause 25: The method according to any of Clauses 22 to 24, wherein the monolithic metal body has a uniform nanoporosity ranging from about 2% to about 30%.
      Clause 26: The method according to Clause 22, further comprising the step of repeating steps a) to c) on a second face of the printed circuit board.
      Clause 27: The method according to Clause 22, wherein the step of forming the one or more structures in the printed circuit board comprises machining the one or more structures in the printed circuit board.
      Clause 28: The method according to Clause 22, wherein the step of filling the one or more structures in the printed circuit board comprises dispensing the conductive material into each of the one or more structures.
      Clause 29: The method according to Clause 22, wherein the step of filling the one or more structures in the printed circuit board comprises the step of screen printing.
      Clause 30: The method according to Clause 22, further comprising the step of inserting a conductive wire within at least a portion of the conductive material and extending out of the printed circuit board prior to step c), wherein the conductive wire is connectable to an external device.
      Clause 31: The method according to any of Clauses 22 to 30, wherein the one or more structures are selected from the group consisting of trenches, grooves, conduits, vias, fully or partially embedded wires, fully or partially embedded cables, and combinations of any of the foregoing.

What is claimed is:

1. A printed circuit board assembly comprising:
a. a printed circuit board, wherein the at least one printed circuit board comprises at least one insulating layer;
b. one or more structures formed in the printed circuit board, wherein the one or more structures extend substantially across a dimension of the printed circuit board and are at least substantially filled with a conductive material to form a conductive structure;
wherein each of the one or more conductive structures are configured to transmit direct current across the dimension of the printed circuit board.

2. The printed circuit board assembly according to claim 1, wherein the conductive material comprises a monolithic block of bulk metal formed from a consolidation of a metal nanoparticle paste composition.

3. The printed circuit board assembly according to claim 2, wherein the monolithic block of bulk metal is a monolithic block of copper formed from the consolidation of a copper nanoparticle paste composition.

4. The printed circuit board assembly according to claim 2, wherein the metal nanoparticle paste composition is formulated to limit shrinkage during consolidation of the metal nanoparticle composition.

5. The printed circuit board assembly according to claim 2, wherein during consolidation, the metal nanoparticle paste composition forms the monolithic metal body that fills each of the one or more structures, wherein the monolithic metal body has a uniform nanoporosity ranging from about 2% to about 30%.

6. The printed circuit board assembly according to claim 1, wherein at least some of the one or more structures have a depth of between about 150 microns and about 10 mm, preferably about 250 microns and about 3 mm, more preferably about 500 microns and about 5 mm.

7. The printed circuit board assembly according to claim 1, wherein at least some of the one or more structures have a width of between about 100 microns and about 30 mm, more preferably about 500 microns and about 25 mm.

8. The printed circuit board assembly according to claim 1, further comprising a conductive wire disposed within at least a portion of the conductive material and extending out of the printed circuit board, wherein the wire is connectable to an external device.

9. The printed circuit board assembly according to claim 8, wherein the external device is operatively connected to a source of power for transmitting current into and through the printed circuit board, preferably wherein the source of power comprises a power cord.

10. The printed circuit board assembly according to claim 1, wherein the one or more structures are selected from the group consisting of trenches, grooves, conduits, through-hole vias, coins, fully or partially embedded wires, fully or partially embedded cables, and combinations of any of the foregoing.

11. The printed circuit board assembly according to claim 10, wherein the one or more structures comprises one or more conductive trenches or grooves, wherein the one or more conductive trenches or grooves further comprise one or more bends or branches.

12. The printed circuit board assembly according to claim 11, wherein the one or more bends or branches extend from the one or more trenches or grooves to one or more edges of the printed circuit board.

13. The printed circuit board assembly according to claim 11, wherein the one or more bends or branches form an angle with the one or more trenches or grooves, wherein angle between the at least one or more bend and the trench or groove is between about 20 degrees to about 90 degrees, more preferably about 30 degrees to about 80 degrees, more preferably about 40 degrees to about 70 degrees.

14. The printed circuit board assembly according to claim 10, wherein each of the one or more structures has a trapezoidal cross-sectional shape.

15. The printed circuit board assembly according to claim 14, wherein the trapezoidal cross sectional shape is wider at the top of the at least one trench and smaller at the bottom of the at least one trench or groove.

16. The printed circuit board assembly according to claim 14, wherein each of the one or more structures has substantially the same cross-sectional shape across the entire length of the each of the one or more structures.

17. The printed circuit board assembly according to claim 1, further comprising one or more structures formed in a second face of the at least one printed circuit board, wherein the one or more structures extend substantially across a dimension of the printed circuit board, wherein the one or more conductive structures are at least substantially filled with a conductive material.

18. The printed circuit board assembly according to claim 10, wherein the one or more structures comprise one or more through-hole power vias and/or one or more coins, each of the one or more through-hole power vias and/or coins extending from a first lateral surface to a second lateral surface of the printed circuit board.

19. The printed circuit board assembly according to claim 18, wherein each of the one or more through-hole power vias and/or one coins has a cross-sectional shape selected from the group consisting of circle, oval, multi-sided polygon, square, and rectangle.

20. The printed circuit board assembly according to claim 18, wherein each of the one or more through-hole power vias and/or one or more coins is operatively connected to a power source for transmitting current into and through the printed circuit board.

21. The printed circuit board assembly according to claim 20, wherein the printed circuit board assembly is operatively connected to a heat sink or a thermal ground plane for dissipating heat.

22. A method comprising:
a. forming one or more structures in a printed circuit board, wherein the printed circuit board comprises at least one insulating layer;
b. filling each of the one or more structures with a conductive material to form one or more conductive structures, wherein the conductive material comprises a metal nanoparticle paste composition; and
c. consolidating the conductive material using heat and/or pressure to form a monolithic metal body within each of the one or more structures, wherein the monolithic metal body at least substantially fills each of the one or more structures;
wherein the monolithic metal body transmits direct current across the printed circuit board through the one or more conductive structures when connected to a power source.

23. The method according to claim 22, wherein the metal nanoparticle paste composition comprises copper nanoparticles and the monolithic metal body is a monolithic copper body.

24. The method according to claim 23, wherein monolithic copper body has a conductivity of at least 50% International Annealed Copper Standard (% IACS), preferably at least 60% IACS, or at least 70% IACS, or between 60 and 95% IACS.

25. The method according to claim 22, wherein the monolithic metal body has a uniform nanoporosity ranging from about 2% to about 30%.

26. The method according to claim 22, further comprising the step of repeating steps a) to c) on a second face of the printed circuit board.

27. The method according to claim 22, wherein the step of forming the one or more structures in the printed circuit board comprises machining the one or more structures in the printed circuit board.

28. The method according to claim 22, wherein the step of filling the one or more structures in the printed circuit board comprises dispensing the conductive material into each of the one or more structures.

29. The method according to claim 22, wherein the step of filling the one or more structures in the printed circuit board comprises the step of screen printing.

30. The method according to claim 22, further comprising the step of inserting a conductive wire within at least a portion of the conductive material and extending out of the printed circuit board prior to step c), wherein the conductive wire is connectable to an external device.

31. The method according to claim 22, wherein the one or more structures are selected from the group consisting of trenches, grooves, conduits, vias, through-hole power vias, coins, fully or partially embedded wires, fully or partially embedded cables, and combinations of any of the foregoing.
